(19) United States
(12) Patent Application Publication
(10) Pub. No.: US 2026/0096365 A1
(43) Pub. Date: Apr. 2, 2026

(54) COMPOSITION, METHOD OF TREATING METAL-CONTAINING FILM AND METHOD OF MANUFACTURING ELECTRONIC DEVICE

(71) Applicant: Samsung Electronics Co., Ltd., Suwon-si (KR)

(72) Inventors: Byungjoon KANG, Suwon-si (KR); Sungmin KIM, Suwon-si (KR); Jungah KIM, Suwon-si (KR); Insun PARK, Suwon-si (KR); Sangwon BAE, Suwon-si (KR); Minjae SUNG, Suwon-si (KR); Sabyuk YANG, Suwon-si (KR); Kum Hee LEE, Suwon-si (KR); Kyuyoung HWANG, Suwon-si (KR)

(73) Assignee: Samsung Electronics Co., Ltd., Suwon-si (KR)

(21) Appl. No.: 19/337,332

(22) Filed: Sep. 23, 2025

(30) Foreign Application Priority Data
Sep. 30, 2024 (KR) 10-2024-0133255
Sep. 19, 2025 (KR) 10-2025-0134991

(51) Int. Cl. H01L 21/3213; C23F 1/18; C23F 1/20; C23F 1/26; C23F 1/28; C23F 1/30; H10D 64/01

(52) U.S. Cl. CPC H10P 50/266; C23F 1/18; C23F 1/20; C23F 1/26; C23F 1/28; C23F 1/30; H10D 64/01

(57) ABSTRACT

Provided are a composition including an oxidizing agent, a phosphoric acid, an organic acid, and an etching controller and having pH of 2.0 or less, wherein the oxidizing agent includes hydrogen peroxide, an iodine-containing compound, or any combination thereof, and the etching controller includes a hydroxyl-free and nitrogen-containing compound, a method of treating a metal-containing film using the composition, and a method of manufacturing an electronic device by using the composition.

### CROSS-REFERENCE TO RELATED APPLICATION

This application claims the benefit of Korean Patent Applications Nos. 10-2024-0133255, filed on Sep. 30, 2024, and 10-2025-0134991, filed on Sep. 19, 2025, in the Korean Intellectual Property Office, the disclosure of which is incorporated herein in its entirety by reference.

### BACKGROUND

### 1. Field

The disclosure relates to a composition, a method of treating a metal-containing film by using the same, and/or a method of manufacturing an electronic device by using the same.

### 2. Description of the Related Art

In order to meet consumer demands for excellent performance and low cost, improvements in the integration density and reliability of various electronic devices, such as semiconductor devices, are increasingly being explored. However, as the integration density of semiconductor devices increases, damage to the components of the semiconductor device during the manufacturing process may have a greater impact on the reliability and electrical characteristics of the device. In particular, during the manufacturing process of semiconductor devices, various treatment processes such as etching, cleaning, and polishing may be performed on films (for example, metal-containing films). Accordingly, there is a continuing need for compositions having appropriate etch rates, or the like, to more effectively carry out metal-containing film treatment processes.

### SUMMARY

Provided is a composition capable of more effectively controlling the etch rate for various metal-containing films, a method of treating a metal-containing film using the composition, and a method of manufacturing an electronic device using the composition.

Additional aspects will be set forth in part in the description which follows and, in part, will be apparent from the description, or may be learned by practice of the presented embodiments of the disclosure.

According to an aspect of the disclosure, a method of treating a metal-containing film may include:
preparing a substrate including the metal-containing film, the metal-containing film including a first region and a second region; and
contacting the metal-containing film with a composition;
wherein the first region and the second region independently may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof,
wherein a material included in the first region may be different from a material included in the second region,
wherein the composition may include an oxidizing agent, a phosphoric acid, an organic acid, and an etching controller,
wherein the oxidizing agent may include hydrogen peroxide, an iodine-containing compound, or any combination thereof,
wherein the etching controller may include a hydroxyl-free and nitrogen-containing compound,
wherein the hydroxyl-free and nitrogen-containing compound may include a compound represented by Formula 5, a compound represented by Formula 6, or any combination thereof, and
wherein the composition may have a pH of 2 or less,

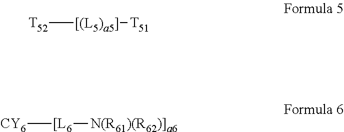

wherein, in Formula 5, L₅ may be *—C(Z₅₁) (Z₅₂)—*′, *—N(Z₅₃)—*′, or *—C(═O)—*′,
in Formula 5, a5 may be an integer from 2 to 30,
in Formula 5, T₅₁ may be *—N(R₅₁) (R₅₂), and T₅₂ is *—N(R₅₃) (R₅₄),
in Formula 6, ring CY₆ may be a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, L₆ may be a single bond or a C₁-C₃₀ alkylene group,
in Formula 6, a6 may be an integer from 1 to 5,
in Formulae 5 and 6, Z₅₁, Z₅₂, Z₅₃, R₅₁, R₅₂, R₅₃, R₅₄, R₆₁, and R₆₂ each independently may be:
hydrogen or an amino group; or
a C₁-C₃₀ alkyl group which is unsubstituted or substituted with an amino group, a mono(C₁-C₃₀ alkyl)amino group, a di(C₁-C₃₀ alkyl)amino group, *—C(═O)—N(Q₅₁) (Q₅₂), or any combination thereof,
Q₅₁ and Q₅₂ each independently may be:
hydrogen; or
a C₁-C₃₀ alkyl group which is unsubstituted or substituted with an amino group, a mono(C₁-C₃₀ alkyl)amino group, a di(C₁-C₃₀ alkyl)amino group, or any combination thereof, and
* and *′ each may indicate a binding site to a neighboring atom.

In some embodiments, the first region may include titanium (Ti), indium (In), aluminum (Al), lanthanum (La), scandium (Sc), gallium (Ga), or any combination thereof, and
the second region may include tungsten (W), molybdenum (Mo), ruthenium (Ru), or any combination thereof.

In some embodiments, the first region may include a metal nitride, a metal oxynitride, or any combination thereof, and
the second region may include a conductive metal.

In some embodiments, the first region may include a titanium nitride, a titanium oxynitride, or any combination thereof, and each of the titanium nitride and the titanium oxynitride optionally further comprises indium (In), aluminum (Al), lanthanum (La), scandium (Sc), gallium (Ga), silicon (Si), or any combination thereof.

In some embodiments, an etching area ratio, which may be a ratio obtained by dividing a first area of the first region exposed for contact with the composition by a second area of the second region exposed for contact with the composition, may be in a range of about 0.05 to about 1.0.

In some embodiments, an amount of the phosphoric acid in the composition may be about 10 wt % to about 85 wt % based on 100 wt % of the composition.

In some embodiments, in Formula 5, i) each L₅ may be *—C(Z₅₁) (Z₅₂)—*′ and a5 may be an integer from 2 to 11, or ii) each L₅ is *—C(Z₅₁) (Z₅₂)—*′ or *—N(Z₅₃)—*′ and a5 is an integer from 5 to 11, and

in Formula 6, ring CY₆ may be a cyclopentane group, a cyclohexane group, a cycloheptane group, a cyclooctane group, a cyclopentene group, a cyclohexene group, a cycloheptene group, a cyclooctene group, a benzene group, a naphthalene group, a piperazine group, a pyrrolidine group, a piperidine group, an azepane group, a tetrahydrofuran group, a tetrahydrothiophene group, a tetrahydro-2H-pyran group, a tetrahydro-2H-thiopyran group, a 4H-pyran-4-one group, a pyridine group, a pyrimidine group, a pyrazine group, a pyridazine group, a triazine group, a carbazole group, a dibenzofuran group, or a dibenzothiophene group.

In some embodiments, the composition may have a pH of about −3.0 to about 1.0.

According to an aspect of the disclosure, a method of manufacturing an electronic device including a transistor is provided. The method may include:
forming a structure including a source and a drain spaced apart from each other and electrically connected to a channel; and
providing a gate electrode and a gate insulating film on the structure, wherein the gate insulating film is between the gate electrode and the channel,
wherein the gate electrode may be provided by:
providing a barrier layer comprising a metal nitride, a metal oxynitride, or any
providing a conductive layer including a conductive metal; and
forming the gate electrode by bringing the barrier layer and the conductive layer into contact with a composition to etch a portion of the barrier layer and a portion of the conductive layer;
wherein the composition may include an oxidizing agent, a phosphoric acid, an organic acid, and an etching controller,
wherein oxidizing agent may include hydrogen peroxide, an iodine-containing compound, or any combination thereof.
wherein the etching controller may include a hydroxyl-free and nitrogen-containing compound,
wherein the hydroxyl-free and nitrogen-containing compound may include a compound represented by Formula 5, a compound represented by Formula 6, or any combination thereof, and
wherein the composition may have a pH of 2 or less,

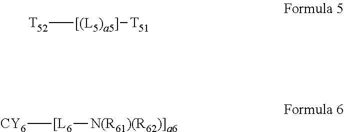

wherein, in Formula 5, L₅ may be *—C(Z₅₁) (Z₅₂)—*′, *—N(Z₅₃)—*′, or *—C(═O)—*′,
in Formula 5, a5 may be an integer from 2 to 30,
in Formula 5, T₅₁ may be *—N(R₅₁) (R₅₂), and T₅₂ may be *—N(R₅₃) (R₅₄),
in Formula 6, ring CY₆ may be a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, L₆ may be a single bond or a C₁-C₃₀ alkylene group,
in Formula 6, a6 may be an integer from 1 to 5,
in Formulae 5 and 6, Z₅₁, Z₅₂, Z₅₃, R₅₁, R₅₂, R₅₃, R₅₄, R₆₁, and R₆₂ are each independently:
hydrogen or an amino group; or
a C₁-C₃₀ alkyl group which may be unsubstituted or substituted with an amino group, a mono(C₁-C₃₀ alkyl)amino group, a di(C₁-C₃₀ alkyl)amino group, *—C(═O)—N (Q₅₁) (Q₅₂), or any combination thereof,
Q₅₁ and Q₅₂ are each independently:
hydrogen; or
a C₁-C₃₀ alkyl group which may be unsubstituted or substituted with an amino group, a mono(C₁-C₃₀ alkyl)amino group, a di(C₁-C₃₀ alkyl)amino group, or any combination thereof, and
* and *′ each may indicate a binding site to a neighboring atom.

In some embodiments, the barrier layer may include a titanium nitride, a titanium oxynitride, or any combination thereof,
each of the titanium nitride and the titanium oxynitride optionally further may include indium (In), aluminum (Al), lanthanum (La), scandium (Sc), gallium (Ga), silicon (Si), or any combination thereof, and
the conductive layer may include tungsten (W), molybdenum (Mo), ruthenium (Ru), or any combination thereof.

In some embodiments, the method may further include:
after the forming of the gate electrode by bringing the barrier layer and the conductive layer into contact with the composition to etch the portion of the barrier layer to provide and the portion of the conductive layer, such that an etched barrier layer and an etched conductive layer are formed, providing an insulating layer on a surface of the etched barrier layer and a surface of the etched conductive layer.

According to an aspect of the disclosure, a composition includes:
an oxidizing agent, a phosphoric acid, an organic acid, and an etching controller,
wherein the oxidizing agent may include hydrogen peroxide, an iodine-containing compound, or any combination thereof,
wherein the etching controller may include a hydroxyl-free and nitrogen-containing compound,
wherein the hydroxyl-free and nitrogen-containing compound may include a compound represented by Formula 5, a compound represented by Formula 6, or any combination thereof, and
wherein the composition may have a pH of 2 or less:

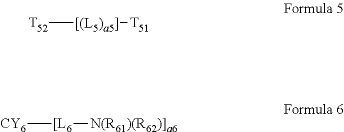

wherein,
in Formula 5, L₅ may be *—C(Z₅₁) (Z₅₂)—*′, *—N(Z₅₃)—*′, or *—C(═O)—*′,
in Formula 5, a5 may be an integer from 2 to 30,
in Formula 5, T₅₁ may be *—N(R₅₁) (R₅₂), and T₅₂ may be *—N(R₅₃) (R₅₄),
in Formula 6, ring CY₆ may be a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, L₆ may be a single bond or a C₁-C₃₀ alkylene group,
in Formula 6, a6 may be an integer from 1 to 5,
in Formulae 5 and 6, Z₅₁, Z₅₂, Z₅₃, R₅₁, R₅₂, R₅₃, R₅₄, R₆₁, and R₆₂ are each independently:
hydrogen or an amino group; or
a C₁-C₃₀ alkyl group which may be unsubstituted or substituted with an amino group, a mono(C₁-C₃₀ alkyl)amino group, a di(C₁-C₃₀ alkyl)amino group, *—C(═O)—N (Q₅₁) (Q₅₂), or any combination thereof,
Q₅₁ and Q₅₂ are each independently:
hydrogen; or
a C₁-C₃₀ alkyl group which may be unsubstituted or substituted with an amino group, a mono(C₁-C₃₀ alkyl)amino group, a di(C₁-C₃₀ alkyl)amino group, or any combination thereof, and
* and *′ each indicate a binding site to a neighboring atom.

According to another aspect of the disclosure, a method of treating a metal-containing film includes:
preparing a substrate on which is provided a metal-containing film including a first region and a second region, and
contacting the metal-containing film with the composition,
wherein the first region and the second region independently include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof, and
the material included in the first region may be different from the material included in the second region.

According to another aspect of the disclosure, a method of manufacturing an electronic device including a transistor is provided,
wherein the transistor may include:
a channel,
a source and a drain spaced apart from each other and electrically connected to the channel and,
a gate electrode, and
a gate insulating film disposed between the gate electrode and the channel, and
wherein the method may include,
providing a barrier layer including a metal nitride, a metal oxynitride, or any combination thereof;
providing a conductive layer including a conductive metal; and
forming the gate electrode by bringing the barrier layer and the conductive layer into contact with the composition to etch a portion of the barrier layer and a portion of the conductive layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 2 are schematic views briefly illustrating an embodiment of a method of treating a metal-containing film;

FIG. 1B is a schematic view showing the surface of a metal-containing film (20A) of FIG. 1A that may be brought into contact with a composition (30);

FIGS. 3 and 4 are schematic views briefly illustrating other embodiments of a method of treating a metal-containing film;

FIG. 5 is a schematic plan view of an electronic device according to an embodiment;

FIG. 6A is a perspective view of an embodiment of the electronic device illustrated in FIG. 5;

FIG. 6B is a perspective view of another embodiment of the electronic device shown in FIG. 5;

FIGS. 7 to 9 are schematic views briefly illustrating parts of a process of manufacturing the transistor structure shown in FIG. 6A;

FIG. 10 is a process flowchart of an embodiment of a method of manufacturing an electronic device;

FIG. 11A is an 1H NMR data of Compound A1 after mixing with high-concentration (70 wt %) phosphoric acid and heating at high temperature (60° C.);

FIG. 11B is an 1H NMR data of PEI after mixing with high-concentration (70 wt %) phosphoric acid and heating at high temperature (60° C.);

FIG. 12 is a transmission electron microscope (TEM) image of Sample 1 in which a molybdenum film and a titanium nitride-containing film are arranged between two silicon oxide films;

FIG. 13A is a TEM image of Sample 1 immersed in the composition of Example 1; and

FIG. 13B is a TEM image of Sample 1 immersed in the composition of Comparative Example C2.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The use of any and all examples, and/or exemplary language provided herein, is intended merely to better illuminate technical ideas and does not pose a limitation on the scope of embodiments unless otherwise claimed.

### Metal-Containing Film

The metal-containing film may include an alkali metal (for example, sodium (Na), potassium (K), rubidium (Rb), cesium (Cs), or the like), an alkaline earth metal (for example, beryllium (Be), magnesium (Mg), calcium (Ca), strontium (Sr), barium (Ba), or the like), a lanthanide metal (for example, lanthanum (La), europium (Eu), terbium (Tb), ytterbium (Yb), or the like), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), or the like), post-transition metals (for example, aluminum (Al), gallium (Ga), indium (In), thallium (TI), tin (Sn), bismuth (Bi), or the like), or any combination thereof.

According to an embodiment, the metal-containing film may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof.

According to another embodiment, the metal-containing film may include two or more different types of metals.

According to another embodiment, the metal-containing film may include titanium.

According to another embodiment, the metal-containing film may i) include titanium (Ti), and ii) optionally further include, in addition to titanium, indium (In), aluminum (Al), lanthanum (La), scandium (Sc), gallium (Ga), tungsten (W), molybdenum (Mo), ruthenium (Ru), zinc (Zn), hafnium (Hf), silicon (Si), or any combination thereof.

The metal-containing film may include a metal, a metal nitride, a metal oxide, a metal oxynitride or any combination thereof.

According to an embodiment, the metal-containing film may include a metal, a metal nitride, a metal oxide, a metal oxynitride, or any combination thereof, and each of the metal, the metal of the metal nitride, the metal of the metal oxide, and the metal of the metal oxynitride may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof.

According to another embodiment, the metal-containing film may include a metal nitride, a metal oxynitride, or any combination thereof as described above (for example, a titanium nitride, a titanium oxynitride, or any combination thereof, or the like).

According to another embodiment, the metal-containing film may include a metal as described above (for example, a conductive metal such as tungsten, molybdenum, and ruthenium).

According to another embodiment, the metal-containing film may include i) a metal nitride, a metal oxynitride, or any combination thereof as described above (for example, a titanium nitride, a titanium oxynitride, or any combination thereof, or the like) and ii) a metal as described above (for example, a conductive metal such as tungsten, molybdenum, and ruthenium).

According to another embodiment, the metal-containing film may include a titanium nitride, a titanium oxynitride, or any combination thereof, and may further include tungsten, molybdenum, ruthenium, or any combination thereof, in addition to the titanium nitride, the titanium oxynitride, or any combination thereof. Each of the titanium nitride and titanium oxynitride may optionally further include indium, aluminum, lanthanum, scandium, gallium, silicon, or any combination thereof.

According to another embodiment, the metal-containing film may include a titanium nitride, a titanium nitride further including aluminum (for example, TiAlN), a titanium nitride further including lanthanum, a titanium nitride further including silicon (for example, TiSiN), or the like.

The metal-containing film may be a single-layer structure including one or more types of materials or a multi-layer structure including different materials. The plurality of the films included in the multilayer structure may be vertically stacked or horizontally arranged with respect to the substrate. The single-layer structure and the multi-layer structure may have various three-dimensional patterns (for example, via holes, trenches, or the like).

According to an embodiment, the metal-containing film includes a first region and a second region, wherein the first region and the second region independently may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof, and the material included in the first region may be different from the material included in the second region.

According to another embodiment, the first region may include titanium.

According to another embodiment, the first region may i) include titanium (Ti), and ii) in addition to titanium, optionally may further include indium (In), aluminum (Al), lanthanum (La), scandium (Sc), gallium (Ga), tungsten (W), molybdenum (Mo), ruthenium (Ru), zinc (Zn), hafnium (Hf), silicon (Si), or any combination thereof.

According to another embodiment, the second region may include tungsten (W), molybdenum (Mo), ruthenium (Ru), or any combination thereof.

According to another embodiment, the first region may include titanium (Ti), indium (In), aluminum (Al), lanthanum (La), scandium (Sc), gallium (Ga), or any combination thereof, and the second region may include tungsten (W), molybdenum (Mo), ruthenium (Ru), or any combination thereof.

According to another embodiment, the first region may include a metal nitride, a metal oxynitride, or any combination thereof, and the second region may include a conductive metal.

For example, the first region may have i) a single-layer structure of a metal nitride film, ii) a single-layer structure of a metal oxynitride film, or iii) a double-layer structure of a metal nitride film and a metal oxynitride film.

According to another embodiment, the first region may include a titanium nitride, a titanium oxynitride, or any combination thereof, wherein each of the titanium nitride and the titanium oxynitride may optionally further include indium (In), aluminum (Al), lanthanum (La), scandium (Sc), gallium (Ga), silicon (Si), or any combination thereof.

According to another embodiment, the first region may include a titanium nitride, a titanium nitride further including aluminum (for example, TiAlN), a titanium nitride further including lanthanum, a titanium nitride further including silicon (for example, TiSiN), and the like.

As used herein, the etching of any film may refer to that at least a portion of the material constituting the film is removed.

### Composition

The composition may include an oxidizing agent, a phosphoric acid, an organic acid, and an etching controller.

The composition may be used in various treatment processes for the metal-containing film described herein, such as etching, cleaning, and polishing processes.

The composition may further include a polar solvent (e.g., water).

According to an embodiment, the composition may not include a fluorine-containing compound. Although not intended to be limited by any particular theory, when the composition includes a fluorine-containing compound, during treatment processes for the metal-containing film using the same, adjacent materials, such as various oxides or the like, disposed adjacent to the metal-containing film as described below may be damaged, resulting in a deterioration in the performance of electronic devices and/or semiconductor devices.

According to an embodiment, the composition may consist of (or consist essentially of) an oxidizing agent, a phosphoric acid, an organic acid, an etching controller, and a polar solvent (e.g., water). In some embodiments, the composition may include an oxidizing agent, a phosphoric acid, an organic acid, and an etching controller, and a remaining amount of the composition may be water.

### Oxidizing Agent

The oxidizing agent serves to etch at least a portion of the metal-containing film and may include hydrogen peroxide, an iodine-containing compound, or any combination thereof.

According to an embodiment, the oxidizing agent may include hydrogen peroxide, periodic acid (H₅IO₆ and/or HIO₄), iodic acid (HIO₃), or any combination thereof.

According to an embodiment, the oxidizing agent may include at least one of hydrogen peroxide and periodic acid.

According to another embodiment, the oxidizing agent may include hydrogen peroxide.

According to another embodiment, the oxidizing agent may include periodic acid.

According to another embodiment, the oxidizing agent may be hydrogen peroxide.

According to another embodiment, the oxidizing agent may be periodic acid.

According to another embodiment, the composition may not include a fluorine-containing compound (for example, HF, NH₄F, etc.) as an oxidizing agent. Without being limited by any particular theory, when the composition includes a fluorine-containing compound as an oxidizing agent, in treating the metal-containing film by using the composition, adjacent materials, for example various oxides, arranged adjacent to the metal-containing film as described below may be damaged, resulting in a deterioration in the performance of an electronic device and/or a semiconductor device.

An amount (weight) of the oxidizing agent may be, for example, based on 100 wt % of the composition, about 0.001 wt % to about 3 wt %, about 0.001 wt % to about 1 wt %, about 0.001 wt % to about 0.7 wt %, about 0.001 wt % to about 0.5 wt %, about 0.005 wt % to about 3 wt %, about 0.005 wt % to about 1 wt %, about 0.005 wt % to about 0.7 wt %, about 0.005 wt % to about 0.5 wt %, about 0.01 wt % to about 3 wt %, about 0.01 wt % to about 1 wt %, about 0.01 wt % to about 0.7 wt %, about 0.01 wt % to about 0.5 wt %, about 0.02 wt % to about 3 wt %, about 0.02 wt % to about 1 wt %, about 0.02 wt % to about 0.7 wt %, or about 0.02 wt % to about 0.5 wt %.

According to another embodiment, the oxidizing agent may include hydrogen peroxide and an amount (weight) of the hydrogen peroxide may be, for example, based on 100 wt % of the composition, about 0.001 wt % to about 3 wt %, about 0.001 wt % to about 1 wt %, about 0.001 wt % to about 0.7 wt %, about 0.001 wt % to about 0.5 wt %, about 0.01 wt % to about 3 wt %, about 0.01 wt % to about 1 wt %, about 0.01 wt % to about 0.7 wt %, about 0.01 wt % to about 0.5 wt %, about 0.02 wt % to about 3 wt %, about 0.02 wt % to about 1 wt %, about 0.02 wt % to about 0.7 wt %, about 0.02 wt % to about 0.5 wt %, about 0.1 wt % to about 3 wt %, about 0.1 wt % to about 1 wt %, about 0.1 wt % to about 0.7 wt %, about 0.1 wt % to about 0.5 wt %, about 0.3 wt % to about 3 wt %, about 0.3 wt % to about 1 wt %, about 0.3 wt % to about 0.7 wt %, about 0.3 wt % to about 0.5 wt %, or about 0.5 wt % to about 0.7 wt %.

According to another embodiment, the oxidizing agent may include periodic acid and an amount (weight) of the periodic acid may be, for example, based on 100 wt % of the composition, about 0.001 wt % to about 3 wt %, about 0.001 wt % to about 1 wt %, about 0.001 wt % to about 0.5 wt %, about 0.001 wt % to about 0.1 wt %, about 0.001 wt % to about 0.05 wt %, about 0.001 wt % to about 0.02 wt %, about 0.005 wt % to about 3 wt %, about 0.005 wt % to about 1 wt %, about 0.005 wt % to about 0.5 wt %, about 0.005 wt % to about 0.1 wt %, about 0.005 wt % to about 0.05 wt %, about 0.005 wt % to about 0.02 wt %, about 0.01 wt % to about 3 wt %, about 0.01 wt % to about 1 wt %, about 0.01 wt % to about 0.5 wt %, about 0.01 wt % to about 0.1 wt %, about 0.01 wt % to about 0.05 wt %, about 0.01 wt % to about 0.02 wt %, about 0.02 wt % to about 3 wt %, about 0.02 wt % to about 1 wt %, about 0.02 wt % to about 0.5 wt %, about 0.02 wt % to about 0.1 wt %, about 0.02 wt % to about 0.05 wt %, or about 0.02 wt % to about 0.03 wt %.

### Phosphoric Acid

The phosphoric acid may serve to etch at least a portion of the metal-containing film, together with the oxidizing agent.

According to an embodiment, the composition may not include sulfuric acid, hydrochloric acid, or nitric acid. Without being limited by any particular theory, when sulfuric acid, hydrochloric acid, or nitric acid is used together with an oxidizing agent as described above, the stability of the composition may be reduced, making the composition unsuitable for use in a metal-containing film treatment process.

An amount (weight) of the phosphoric acid may be, for example, based on 100 wt % of the composition, about 10 wt % to about 85 wt %, about 15 wt % to about 85 wt %, about 20 wt % to about 85 wt %, about 25 wt % to about 85 wt %, about 30 wt % to about 85 wt %, about 35 wt % to about 85 wt %, about 40 wt % to about 85 wt %, about 45 wt % to about 85 wt %, about 50 wt % to about 85 wt %, about 55 wt % to about 85 wt %, about 10 wt % to about 80 wt %, about 15 wt % to about 80 wt %, about 20 wt % to about 80 wt %, about 25 wt % to about 80 wt %, about 30 wt % to about 80 wt %, about 35 wt % to about 80 wt %, about 40 wt % to about 80 wt %, about 45 wt % to about 80 wt %, about 50 wt % to about 80 wt %, about 55 wt % to about 80 wt %, about 10 wt % to about 75 wt %, about 15 wt % to about 75 wt %, about 20 wt % to about 75 wt %, about 25 wt % to about 75 wt %, about 30 wt % to about 75 wt %, about 35 wt % to about 75 wt %, about 40 wt % to about 75 wt %, about 45 wt % to about 75 wt %, about 50 wt % to about 75 wt %, about 55 wt % to about 75 wt %, about 10 wt % to about 70 wt %, about 15 wt % to about 70 wt %, about 20 wt % to about 70 wt %, about 25 wt % to about 70 wt %, about 30 wt % to about 70 wt %, about 35 wt % to about 70 wt %, about 40 wt % to about 70 wt %, about 45 wt % to about 70 wt %, about 50 wt % to about 70 wt %, about 55 wt % to about 70 wt %, or about 60 wt % to about 70 wt %.

### Organic Acid

The organic acid may serve to control the etching rate of at least a portion of the metal-containing film.

The organic acid may include a monocarboxylic acid, a dicarboxylic acid, a tricarboxylic acid, or any combination thereof.

The number of carbon atoms included in each of the monocarboxylic acid, the dicarboxylic acid, and the tricarboxylic acid may be 1 to 31, 1 to 20, 1 to 10, 1 to 5, or 2 to 3.

According to an embodiment, the organic acid may include:
HCOOH;
an aliphatic compound having 1 to 30 carbon atoms (for example, 1 to 20 carbon atoms or 1 to 15 carbon atoms), or an aromatic compound having 6 to 30 carbon atoms (for example, 6 to 15 carbon atoms or 6 to 10 carbon atoms), each substituted with at least one carboxylic group (*—COOH) (for example, 1, 2, or 3 carboxylic groups); or
any combination thereof,
wherein at least one hydrogen of the aliphatic compound and the aromatic compound may be optionally additionally substituted with a hydroxyl group, a thiol group, an amino group, a C₁-C₁₀ alkyl group (for example, a C₁-C₅ alkyl group), a C₁-C₁₀ alkoxy group (for example, a C₁-C₅ alkoxy group), a C₁-C₁₀ alkylthio group (for example, a C₁-C₅ alkylthio group), a mono(C₁-C₁₀ alkyl)amino group (for example, a mono(C₁-C₅ alkyl)amino group), a di(C₁-C₁₀ alkyl)amino group (for example, a di(C₁-C₅ alkyl)amino group), a phenyl group, or any combination thereof.

According to an embodiment, the aliphatic compound may be a saturated aliphatic compound (for example, an alkane, a cycloalkane, etc.) or an unsaturated aliphatic compound (for example, an alkene, an alkyne, a cycloalkene, etc.).

According to another embodiment, the aliphatic compound may be an acyclic aliphatic compound (for example, an alkane, an alkene, an alkyne, etc.) or a cyclic aliphatic compound (for example, a cycloalkane, a cycloalkene, adamantane, norbornane, etc.).

According to another embodiment, the aliphatic compound may be a straight-chain aliphatic compound (for example, CH₃—CH₂—CH₂—CH₂—CH₃, etc.) or a branched aliphatic compound (for example, CH₃—CH(CH₃)—CH₂—CH₃, CH₃—C(CH₃)₂—CH₃, etc.).

According to another embodiment, the aromatic compound may be benzene.

According to another embodiment, the organic acid may include formic acid, acetic acid, propionic acid, butyric acid, valeic acid, lauric acid, oxalic acid, malonic acid, glutaric acid, adipic acid, gallic acid, succinic acid, malic acid, maleic acid, crotonic acid, fumaric acid, ascorbic acid, glutamic acid, citric acid, tartaric acid, glycolic acid, lactic acid, benzoic acid, salicylic acid, or any combination thereof.

An amount of the organic acid may be, based on 100 wt % of the composition, about 0.1 wt % to about 15 wt %, about 0.5 wt % to about 15 wt %, about 1 wt % to about 15 wt %, about 3 wt % to about 15 wt %, about 5 wt % to about 15 wt %, about 7 wt % to about 15 wt %, about 0.1 wt % to about 13 wt %, about 0.5 wt % to about 13 wt %, about 1 wt % to about 13 wt %, about 3 wt % to about 13 wt %, about 5 wt % to about 13 wt %, about 7 wt % to about 13 wt %, about 7 wt % to about 10 wt %, or about 10 wt % to about 13 wt %.

### Etching Controller

The etching controller, together with the organic acid, may serve to control the etching rate and the like by interacting with various metal atoms in the metal-containing film, which is a film to be treated.

The etching controller may include a hydroxyl-free and nitrogen-containing compound. The term “hydroxyl-free and nitrogen-containing compound” refers to a compound not including a hydroxyl group and including at least one nitrogen atom as a molecular constituent.

Without being limited by any particular theory, when a hydroxyl group-containing and nitrogen-containing compound (for example, an alkanolamine, etc.) is used together with an oxidizing agent as described above, due to the high hydrophilicity of the hydroxyl group included in the hydroxyl-containing and nitrogen-containing compound, the interaction with various metal atoms in the metal-containing film may not be well achieved, and thus effective etching rate control may not be achieved.

According to another embodiment, the hydroxyl-free and nitrogen-containing compound may include a compound represented by Formula 5 included in a polyalkylene polyamine, a compound represented by Formula 6 included in a cyclic group-containing amine, or any combination thereof (that is, the compound represented by Formula 5 and the compound represented by Formula 6):

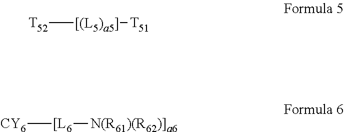

wherein, in Formula 5, L₅ may be *—C(Z₅₁) (Z₅₂)—*′, *—N(Z₅₃)—*′, or *—C(═O)—*′, in Formula 5, a5 may be an integer from 2 to 30,
in Formula 5, T₅₁ may be *—N(R₅₁) (R₅₂), and T₅₂ may be *—N(R₅₃) (R₅₄),
in Formula 6, ring CY₆ may be a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, L₆ may be a single bond or a C₁-C₃₀ alkylene group,
in Formula 6, a6 may be an integer from 1 to 5,
in Formulae 5 and 6, Z₅₁, Z₅₂, Z₅₃, R₅₁, R₅₂, R₅₃, R₅₄, R₆₁, and R₆₂ may each independently be:
hydrogen or an amino group (*—NH₂); or
a C₁-C₃₀ alkyl group which is unsubstituted or substituted with an amino group, a mono(C₁-C₃₀ alkyl)amino group, a di(C₁-C₃₀ alkyl)amino group, *—C(═O)—N(Q₅₁) (Q₅₂), or any combination thereof, and
Q₅₁ and Q₅₂ may each independently be:
hydrogen; or
a C₁-C₃₀ alkyl group which is unsubstituted or substituted with an amino group, a mono(C₁-C₃₀ alkyl)amino group, a di(C₁-C₃₀ alkyl)amino group, or any combination thereof, and
* and *′ each indicate a binding site to a neighboring atom.

According to another embodiment, each L₅ in Formula 5 may be *—C(Z₅₁) (Z₅₂)—*′.

According to another embodiment, each L₅ in Formula 5 may be *—C(Z₅₁) (Z₅₂)—*′ or *—N(Z₅₃)—*′.

According to another embodiment, a5 in Formula 5 may be an integer from 2 to 25, an integer from 2 to 20, an integer from 2 to 15, or an integer from 2 to 11.

According to another embodiment, each L₅ in Formula 5 may be *—C(Z₅₁) (Z₅₂)—*′, and a5 may be an integer from 2 to 11.

According to another embodiment, each L₅ may be *—C(Z₅₁) (Z₅₂)—*′ or *—N(Z₅₃)—*′ and a5 may be an integer from 5 to 11.

According to another embodiment, each L₅ may be *—C(Z₅₁) (Z₅₂)—*′ or *—N(Z₅₃)—*′, and the number of *—N(Z₅₃)—*′ may be 1, 2, 3, or 4.

According to another embodiment, ring CY₆ in Formula 6 may be a saturated or unsaturated carbocyclic group having 5 to 10 carbon atoms, or a saturated heterocyclic group having 2 to 10 carbon atoms.

According to another embodiment, ring CY₆ in Formula 6 may be a cyclopentane group, a cyclohexane group, a cycloheptane group, a cyclooctane group, a cyclopentene group, a cyclohexene group, a cycloheptene group, a cyclooctene group, a benzene group, a naphthalene group, a piperazine group, a pyrrolidine group, a piperidine group, an azepane group, a tetrahydrofuran group, a tetrahydrothiophene group, a tetrahydro-2H-pyran group, a tetrahydro-2H-thiopyran group, a 4H-pyran-4-one group, a pyridine group, a pyrimidine group, a pyrazine group, a pyridazine group, a triazine group, a carbazole group, a dibenzofuran group, or a dibenzothiophene group.

According to another embodiment, Le in Formula 6 may be a single bond or a C₁-C₁₀ alkylene group (for example, a C₁-C₅ alkylene group).

According to another embodiment, a6 in Formula 6 may be 1, 2 or 3.

According to another embodiment, a6 in Formula 6 may be 1 or 2.

According to another embodiment, in Formulae 5 and 6, Z₅₁, Z₅₂, Z₅₃, R₅₁, R₅₂, R₅₃, R₅₄, R₆₁, and R₆₂ may each independently be:
hydrogen or an amino group; or
a C₁-C₁₀ alkyl group which is unsubstituted or substituted with an amino group, a mono(C₁-C₁₀ alkyl)amino group, a di(C₁-C₁₀ alkyl)amino group, *—C(═O)—N(Q₅₁) (Q₅₂), or any combination thereof, and Q₅₁ and Q₅₂ may each independently be:
hydrogen; or
a C₁-C₁₀ alkyl group which is unsubstituted or substituted with an amino group, a mono(C₁-C₁₀ alkyl)amino group, a di(C₁-C₁₀ alkyl)amino group, or any combination thereof.

According to another embodiment, in Formulae 5 and 6, Z₅₁, Z₅₂, Z₅₃, R₅₁, R₅₂, R₅₃, R₅₄, R₆₁, and R₆₂ may each independently be:
hydrogen or an amino group; or
a C₁-C₅ alkyl group which is unsubstituted or substituted with an amino group, a mono(C₁-C₅ alkyl)amino group, a di(C₁-C₅ alkyl)amino group, *—C(═O)—N(Q₅₁) (Q₅₂), or any combination thereof, and
Q₅₁ and Q₅₂ may each independently be:
hydrogen; or
a C₁-C₅ alkyl group which is unsubstituted or substituted with an amino group, a mono(C₁-C₅ alkyl)amino group, a di(C₁-C₅ alkyl)amino group, or any combination thereof.

According to another embodiment, the hydroxyl-free and nitrogen-containing compound may include a compound represented by Formula 51:

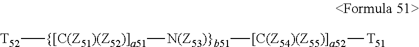

wherein, in Formula 51,
T₅₁, T₅₂, Z₅₁, Z₅₂, and Z₅₃ may each independently be as described herein,
Z₅₄ and Z₅₅ may each independently be as described herein in connection with Z₅₁,
a51 and a52 may each independently be an integer from 2 to 5 (for example, 2 or 3), and
b51 may be an integer from 1 to 7 (for example, 1, 2, or 3).

According to another embodiment, in Formula 51,
i) a51 and a52 may be 2, and b51 may be 1 (for example, Compounds A1, A4 and A28);
ii) a51 and a52 may be 2, and b51 may be 2 (for example, Compounds A5 and A6);
iii) a51 and a52 may be 2, and b51 may be 3 (for example, Compound A2);
iv) a51 and a52 may be 3, and b51 may be 2 (for example, Compound A22); or
v) a51 and a52 may be 3, and b51 may be 1 (for example, Compounds A23 and A24).

According to another embodiment, the hydroxyl-free and nitrogen-containing compound may include a compound represented by Formula 52:

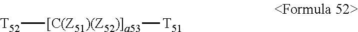

wherein, in Formula 52,
T₅₁, T₅₂, Z₅₁, and Z₅₂ may each independently be as described herein, and
a53 may be an integer from 2 to 25, an integer from 2 to 20, an integer from 2 to 15, or an integer from 2 to 11.

According to another embodiment, in Formula 52, a53 may be an integer from 2 to 11.

According to another embodiment, in Formula 52,
i) a53 may be 11 (for example, Compound A3);
ii) a53 may be 2 (for example, Compounds A7, A8, A21 and A27); or
iii) a53 may be 6 (for example, Compounds A9, A10 and A11).

According to another embodiment, the hydroxyl-free and nitrogen-containing compound may include a compound represented by Formula 6.

According to another embodiment, in Formula 6,
i) L₆ may be a single bond, and a6 may be 2 (for example, Compounds A12 to A17 and A20);
ii) L₆ may be a single bond, and a6 may be 1 (for example, Compound A18);
iii) L₆ may be a single bond, and a6 may be 3 (for example, Compound A19);
iv) L₆ may be a Cs alkylene group, and a6 may be 2 (for example, Compound A25); or
v) L₆ may be a Cs alkylene group, and a6 may be 1 (for example, Compounds A26).

According to another embodiment, the hydroxyl-free and nitrogen-containing compound may include at least one of Compounds A1 to A28:

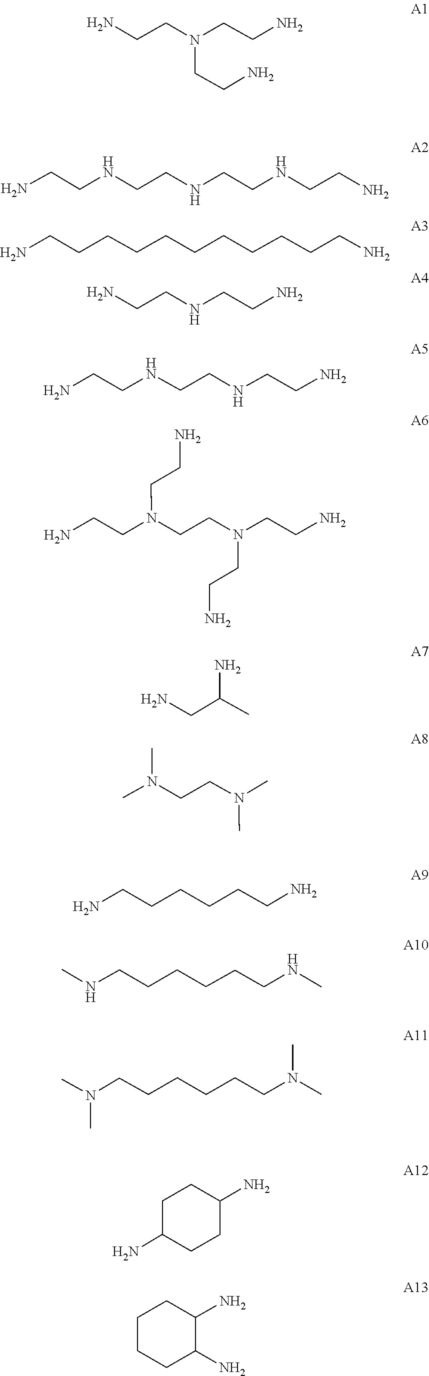

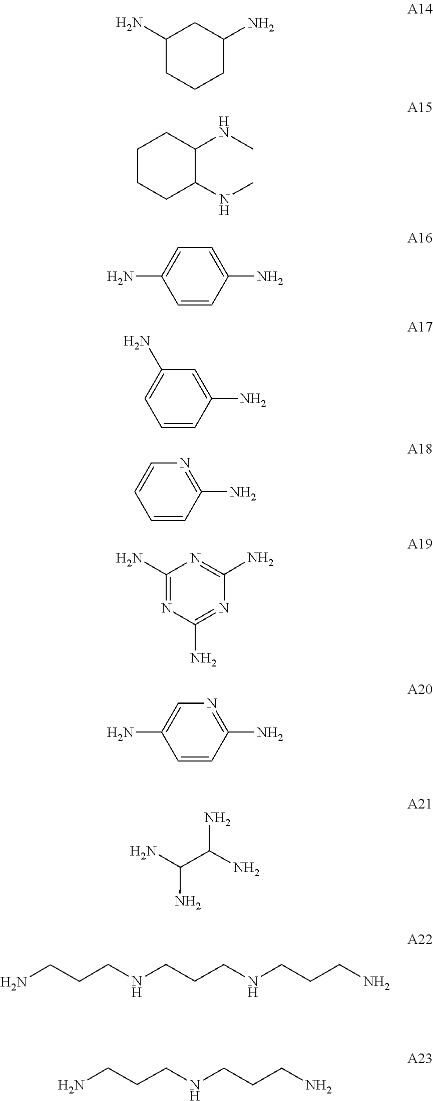

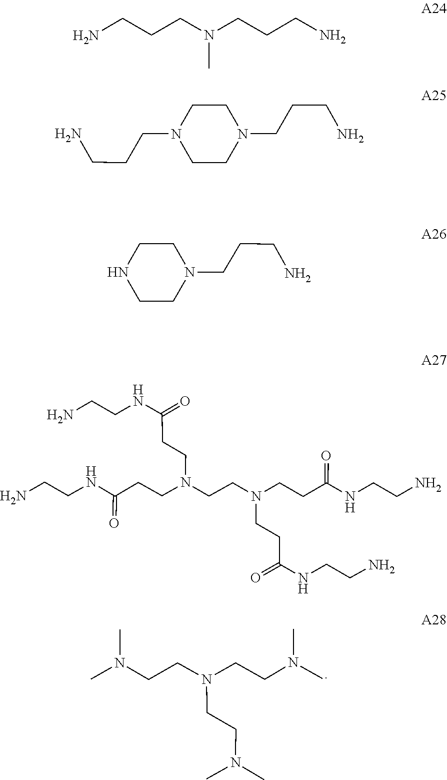

An amount (weight) of the etching controller may be, based on 100 wt % of the composition, about 0.01 wt % to about 5 wt %, about 0.01 wt % to about 4 wt %, about 0.01 wt % to about 3 wt %, about 0.01 wt % to about 2 wt %, about 0.01 wt % to about 1.5 wt %, about 0.01 wt % to about 1 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1.5 wt %, about 0.05 wt % to about 1 wt %, about 0.1 wt % to about 5 wt %, about 0.1 wt % to about 4 wt %, about 0.1 wt % to about 3 wt %, about 0.1 wt % to about 2 wt %, about 0.1 wt % to about 1.5 wt %, about 0.1 wt % to about 1 wt %, about 0.5 wt % to about 5 wt %, about 0.5 wt % to about 4 wt %, about 0.5 wt % to about 3 wt %, about 0.5 wt % to about 2 wt %, about 0.5 wt % to about 1.5 wt %, about 0.5 wt % to about 1 wt %, or about 1 wt % to about 1.5 wt %.

pH

The composition as described above may have a pH of 2.0 or less. For example, the composition as described above may have a pH of 1.7 or less, 1.5 or less, 1.3 or less, 1.0 or less, 0.9 or less, 0.7 or less, 0.5 or less, 0.3 or less, 0.1 or less, or 0.0 or less.

According to an embodiment, the composition may have a pH of about −3.0 to about 2.0, about −3.0 to about 1.7, about −3.0 to about 1.5, about −3.0 to about 1.3, about −3.0 to about 1.0, about −3.0 to about 0.9, about −3.0 to about 0.7, about −3.0 to about 0.5, about −3.0 to about 0, about −2.5 to about 2.0, about −2.5 to about 1.7, about −2.5 to about 1.5, about −2.5 to about 1.3, about −2.5 to about 1.0, about −2.5 to about 0.9, about −2.5 to about 0.7, about −2.5 to about 0.5, about −3.0 to about 0, about −2.0 to about 2.0, about −2.0 to about 1.7, about −2.0 to about 1.5, about −2.0 to about 1.3, about −2.0 to about 1.0, about −2.0 to about 0.9, about −2.0 to about 0.7, about −2.0 to about 0.5, about −2.0 to about 0, about −1.5 to about 2.0, about −1.5 to about 1.7, about −1.5 to about 1.5, about-1.5 to about 1.3, about −1.5 to about 1.0, about −1.5 to about 0.9, about −1.5 to about 0.7, about −1.5 to about 0.5, about −1.5 to about 0, about −1.0 to about 2.0, about −1.0 to about 1.7, about −1.0 to about 1.5, about −1.0 to about 1.3, about −1.0 to about 1.0, about −1.0 to about 0.9, about −1.0 to about 0.7, about −1.0 to about 0.5, about −1.0 to about 0, about −0.6 to about 2.0, about −0.6 to about 1.7, about −0.6 to about 1.5, about −0.6 to about 1.3, about −0.6 to about 1.0, about −0.6 to about 0.9, about −0.6 to about 0.7, about −0.6 to about 0.5, or about −0.6 to about 0. When the composition has a pH within these ranges, the interaction between the etching controller and the metal atoms in the metal-containing film may be better achieved.

According to an embodiment, the composition may include about 0.001 wt % to about 3 wt % of an oxidizing agent, about 10 wt % to about 70 wt % of a phosphoric acid, about 0.1 wt % to about 15 wt % of an organic acid, and about 0.01 wt % to about 3 wt % of an etching controller.

According to another embodiment, the composition may include about 0.001 wt % to about 3 wt % of an oxidizing agent, about 10 wt % to about 75 wt % of a phosphoric acid, about 0.1 wt % to about 13 wt % of an organic acid, and about 0.01 wt % to about 5 wt % of an etching controller.

According to another embodiment, the composition may include about 0.001 wt % to about 3 wt % of an oxidizing agent, about 10 wt % to about 70 wt % of a phosphoric acid, about 0.1 wt % to about 15 wt % of an organic acid, and about 0.01 wt % to about 5 wt % of an etching controller.

According to another embodiment, the composition may be used in a metal-containing film treatment process, for example, etching, cleaning, or polishing process for a metal-containing film. The description of the metal-containing film may be as described herein.

Alternatively, the composition may also be used as an etching by-product remover, a post-etch process by-product remover, an ashing process by-product remover, a cleaning composition, a photoresist (PR) remover, an etching composition for a packaging process, a cleaning agent for a packaging process, a wafer adhesive remover, an etchant, a post-etch residue stripper, an ash residue cleaner, a PR residue stripper, a chemical mechanical polishing (CMP) cleaner, or a post-CMP cleaner.

### Method of Treating a Metal-Containing Film

Using the composition as described above, a metal-containing film including a first region and a second region, wherein the material included in the first region is different from the material included in the second region, may be more effectively treated. For a description of each of the metal-containing film, the first region and the second region, reference is made to the description herein.

According to an embodiment, the first region and the second region may independently include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof.

According to another embodiment, the first region may include titanium (Ti), indium (In), aluminum (Al), lanthanum (La), scandium (Sc), gallium (Ga), or any combination thereof, and the second region may include tungsten (W), molybdenum (Mo), ruthenium (Ru), or any combination thereof.

According to another embodiment, the first region may include a metal nitride, a metal oxynitride, or any combination thereof, and the second region may include a conductive metal.

According to another embodiment, the first region may include a titanium nitride, a titanium oxynitride, or any combination thereof, and each of the titanium nitride and the titanium oxynitride may optionally further include indium (In), aluminum (Al), lanthanum (La), scandium (Sc), gallium (Ga), silicon (Si), or any combination thereof.

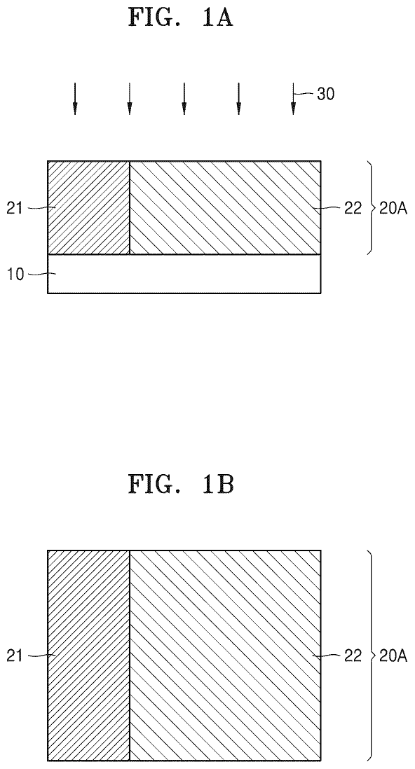

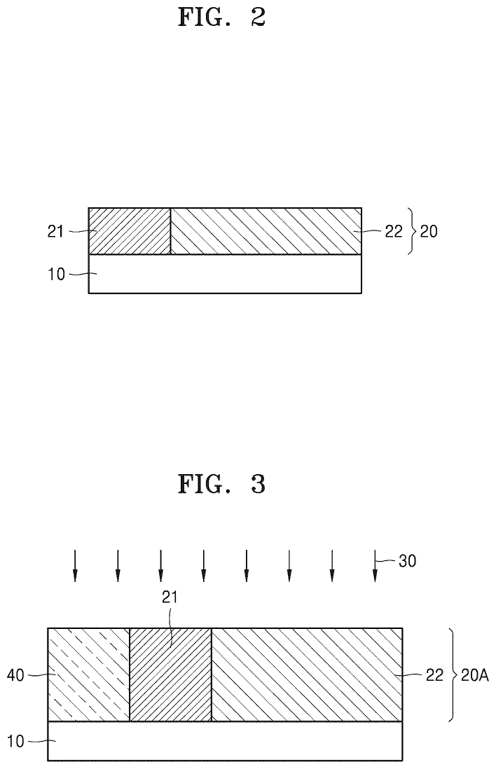

FIGS. 1A and 2 are views schematically illustrating an embodiment of a metal-containing film treatment method.

Referring to FIG. 1A, a substrate 10 having a metal-containing film 20A is provided. Although not shown in FIG. 1A, various circuit elements or the like may optionally be additionally disposed between the substrate 10 and the metal-containing film 20A.

The metal-containing film 20A may include a first region 21 and a second region 22. The first region 21 and the second region 22 may be disposed apart from each other, or may be disposed at least partially in contact with each other, and the metal-containing film 20A may have various patterns. The metal-containing film 20A, including the first region 21 and the second region 22, may come into contact with composition 30, whereby a portion of the metal-containing film 20A may be removed. For example, during an etching, cleaning and/or polishing process of the metal-containing film 20A, the metal-containing film 20A may come into contact with the composition 30. The composition 30 may include the oxidizing agent, the phosphoric acid, the organic acid and the etching controller as described in the specification, and for a detailed description thereof, reference is made to the description herein.

An etching rate ratio, which is obtained by dividing a first etching rate at which the composition 30 etches the first region 21 by a second etching rate at which the composition 30 etches the second region 22, may be 0.04 or more. For example, the etching rate ratio, which is obtained by dividing the first etching rate at which the composition 30 etches the first region 21 by the second etching rate at which the composition 30 etches the second region 22, may be about 0.05 or more, about 0.06 or more, about 0.04 to about 1.0, about 0.05 to about 1.0, about 0.06 to about 1.0, about 0.04 to about 0.5, about 0.05 to about 0.5, about 0.06 to about 0.5, about 0.04 to about 0.3, about 0.05 to about 0.3, about 0.06 to about 0.3, about 0.04 to about 0.2, about 0.05 to about 0.2, about 0.06 to about 0.2, about 0.04 to about 0.15, about 0.05 to about 0.15, about 0.06 to about 0.15, or about 0.06 to about 0.13.

FIG. 1B is a view schematically illustrating a surface of a metal-containing film 20A that may be in contact with a composition 30. An etching area ratio, which is obtained by dividing a first area of a first region 21 exposed for contact with the composition 30 by a second area of a second region 22 exposed for contact with the composition 30, may be about 0.05 to about 1.0, about 0.05 to about 0.9, about 0.05 to about 0.7, about 0.05 to about 0.5, about 0.05 to about 0.4, about 0.05 to about 0.3, or about 0.05 to about 0.2.

When the metal-containing film 20A comes into contact with the composition 30, the high reactivity of metals included in the metal-containing film 20A (for example, a metal such as molybdenum contained in the second region 22) may be controlled through the interaction of the oxidizing agent, the phosphoric acid, the organic acid, and the etching controller included in composition 30. As a result, the etch rate of the region containing a relatively highly reactive metal (for example, the etch rate of second region 22) among the first region 21 and the second region 22 may be properly controlled. Accordingly, portions of both the first region 21 and the second region 22 may be etched such that a metal-containing film pattern 20 having a substantially planar surface (for example, having little or no step height difference between the first region 21 and the second region 22), as illustrated in FIG. 2, may be formed. Furthermore, after the contact process with the composition 30, various by-products derived from the metal-containing film 20A (for example, metal oxides derived from the metal-containing film 20A such as molybdenum oxide) may be substantially absent from the surface of the metal-containing film pattern 20. For example, the presence or absence of the by-products may be verified through analyses such as transmission electron microscopy (TEM), scanning electron microscopy (SEM) or the like.

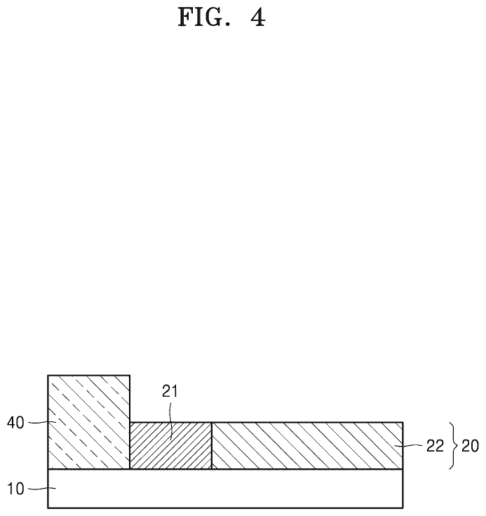

FIGS. 3 and 4 are views schematically illustrating other embodiments of the metal-containing film treatment method.

Referring to FIG. 3, a substrate 10 is provided in which, in addition to the metal-containing film 20A, an additional material 40 is provided adjacent to the metal-containing film 20A. For a description of each of the metal-containing film 20A and the substrate 10 of FIG. 3, reference is made to FIG. 1A.

The additional material 40 in FIG. 3 may be disposed spaced apart from the metal-containing film 20A or may be at least partially in contact with it. As used herein, the term “the additional material 40” refers to a material other than the metal-containing film 20A, which is disposed adjacent to metal-containing film 20A and is located in a region that may be affected by the composition 30 during the treatment of metal-containing film 20A using the composition 30.

The additional material 40 may include at least one of an insulating material and a semiconductor material. The insulating material and semiconductor material may include various known materials.

The insulating material may include various oxides, nitrides, oxynitrides, high-dielectric materials, or combinations thereof. For example, the insulating material may include silicon oxide, silicon nitride, silicon oxynitride, aluminum oxide, hafnium oxide, hafnium oxynitride, zirconium oxide, or a combination thereof. The hafnium oxide and hafnium oxynitride may optionally further include Si, Ta, Ti, Zr or any combination thereof. As another example, the insulating material may include tetraethyl orthosilicate (TEOS), hydrogen silsesquioxane (HSQ), methyl silsesquioxane (MSQ), or the like.

The semiconductor material may be, for example, a material included in a channel or the like, and may include: a Group IV semiconductor material such as silicon, germanium (Ge), silicon-germanium (SiGe), and silicon carbide (SiC); a Group III-V semiconductor material such as gallium arsenide (GaAs), indium arsenide (InAs), and indium phosphide (InP); as well as an oxide semiconductor, a nitride semiconductor, and an oxynitride semiconductors. The oxide semiconductor may include, for example, Indium Gallium Zinc Oxide (IGZO), Indium Tin Zinc Oxide (ITZO), Indium Tin Gallium Oxide (ITGO), Indium Tungsten Oxide (IWO), Indium Tin Oxide (ITO), ZnO, Cu₂O, or any combination thereof.

As shown in FIG. 3, the metal-containing film 20A including the first region 21 and the second region 22, and the additional material 40, may be brought into contact with the composition 30, and a portion of the metal-containing film 20A may be removed. For example, during an etching, cleaning, and/or polishing process of the metal-containing film 20A including the first region 21 and the second region 22, the metal-containing film 20A may be brought into contact with the composition 30. The composition 30 includes the oxidizing agent, the phosphoric acid, the organic acid and the etching controller as described in this specification, and for a detailed description thereof, reference is made to the description herein.

When the metal-containing film 20A comes into contact with the composition 30, a portion of the metal-containing film 20A may be removed. Specifically, upon contact between the metal-containing film 20A and the composition 30, due to the interaction among the oxidizing agent, the phosphoric acid, the organic acid, and the etching controller included in composition 30, the high reactivity of the metal included in the metal-containing film 20A (for example, a metal such as molybdenum included in second region 22) may be controlled. As a result, the etch rate of the region including a relatively highly reactive metal among the first region 21 and the second region 22 (for example, the etch rate of the second region 22) may be appropriately controlled, such that portions of both the first region 21 and the second region 22 are etched. Accordingly, as illustrated in FIG. 4, a metal-containing film pattern 20 having a substantially planar surface (for example, with little or no step height difference between the first region 21 and the second region 22) may be formed. Furthermore, after the contact process with the composition 30, various by-products derived from the metal-containing film 20A (for example, metal oxides derived from the metal-containing film 20A such as molybdenum oxide derived from the metal-containing film 20A) may remain substantially absent on the surface of the metal-containing film pattern 20. In addition, for example, the additional material 40, which includes at least one of an insulating material and a semiconductor material, may remain substantially undamaged by the composition 30.

### Method of Manufacturing an Electronic Device

Using the composition described above, a high-quality electronic device may be manufactured. Accordingly, a method of manufacturing an electronic device using the composition may be provided.

According to an aspect of the disclosure,
a method of manufacturing an electronic device including a transistor is provided,
wherein the transistor includes,
a channel;
a source and a drain spaced apart from each other and electrically connected to the channel;
a gate electrode; and
a gate insulating film disposed between the gate electrode and the channel, wherein the method includes:
providing a barrier layer including a metal nitride, a metal oxynitride, or a
providing a conductive layer including a conductive metal; and
forming the gate electrode by bringing the barrier layer and the conductive layer into contact with the composition to etch a portion of the barrier layer and a portion of the conductive layer.

According to an aspect of the disclosure, a method of manufacturing an electronic device may include: forming a structure including a source and a drain spaced apart from each other and electrically connected to a channel; and providing a gate electrode and a gate insulating film on the structure, wherein the gate insulating film is between the gate electrode and the channel. The gate electrode may be provided by: providing a barrier layer comprising a metal nitride, a metal oxynitride, or any combination thereof; providing a conductive layer including a conductive metal; and forming the gate electrode by bringing the barrier layer and the conductive layer into contact with the composition to etch a portion of the barrier layer and a portion of the conductive layer.

The channel may include, for example, a semiconductor material as described herein. For example, the channel may include: a Group IV semiconductor material such as silicon, germanium (Ge), silicon-germanium (SiGe), and silicon carbide (SiC); a Group III-V semiconductor material such as gallium arsenide (GaAs), indium arsenide (InAs), and indium phosphide (InP); an oxide semiconductor, a nitride semiconductor, and an oxynitride semiconductors. The oxide semiconductor may include, for example, Indium Gallium Zinc Oxide (IGZO), Indium Tin Zinc Oxide (ITZO), Indium Tin Gallium Oxide (ITGO), Indium Tungsten Oxide (IWO), Indium Tin Oxide (ITO), ZnO, Cu₂O, or any combination thereof.

The gate insulating film may include an insulating material capable of electrically insulating the gate electrode and the channel. For example, the gate insulating film may include various oxides, nitrides, oxynitrides, high-k materials, or a combination thereof. For example, the gate insulating film may include silicon oxide, silicon nitride, silicon oxynitride, aluminum oxide, hafnium oxide, hafnium oxynitride, zirconium oxide, or a combination thereof. The hafnium oxide and hafnium oxynitride may optionally further include Si, Ta, Ti, Zr or any combination thereof.

The gate electrode may include a barrier layer and a conductive layer. The barrier layer may be disposed, for example, between the gate insulating film and the conductive layer.

In order to provide the gate electrode, a barrier layer and a conductive layer may be provided. For example, after forming the barrier layer, the conductive layer may be formed on the surface of the barrier layer. However, depending on the structure of the channel and/or gate electrode, various modifications are possible, such as forming the barrier layer on the surface of the conductive layer after the conductive layer is formed.

The barrier layer may be provided to limit and/or prevent peripheral diffusion of a conductive metal (for example, metal ion) included in the conductive layer and/or to facilitate smooth deposition of the conductive layer.

For a detailed description of each of the metal nitride and/or metal oxynitride that may be included in the barrier layer, reference may be made to the description of each of the metal nitride and/or metal oxynitride that may be included in the first region of the metal-containing film in this specification herein.

According to an embodiment, the barrier layer may include a titanium nitride, a titanium oxynitride, or a combination thereof, and each of the titanium nitride and the titanium oxynitride may optionally further comprise indium (In), aluminum (A1), lanthanum (La), scandium (Sc), gallium (Ga), silicon (Si), or any combination thereof.

For a detailed description of the conductive metal that may be included in the conductive layer, reference may be made to the description of the conductive metal that may be included in the second region of the metal-containing film herein.

According to an embodiment, the conductive layer may include tungsten (W), molybdenum (Mo), ruthenium (Ru), or any combination thereof.

Subsequently, the barrier layer and the conductive layer may be brought into contact with the composition described herein to etch a portion of the barrier layer and a portion of the conductive layer, thereby forming the gate electrode.

When the barrier layer and the conductive layer are brought into contact with the composition as described herein, the high reactivity of the conductive metal included in the conductive layer may be controlled through the interaction among the oxidizing agent, the phosphoric acid, the organic acid, and the etching controller in the composition. As a result, the etch rate of the conductive layer may be properly controlled, allowing for etching of portions of both the barrier layer and the conductive layer. Accordingly, a gate electrode having a substantially planar surface (for example, with little or no step height difference between the barrier layer and the conductive layer) may be formed. Furthermore, after the contact process with the composition, various by-products derived from the conductive layer (for example, oxides of the conductive metal) may be substantially absent from the surface of the gate electrode. In addition, since at least one of the channel and gate insulating films disposed adjacent to the gate electrode may be substantially undamaged by the composition, a high-quality electronic device including a gate electrode having a precise pattern may be manufactured without damage to an area adjacent to the gate electrode.

The electronic device may be a semiconductor memory device.

For example, the electronic device may include a volatile memory device, such as a dynamic random access memory (“DRAM”) device or a static random access memory (“SRAM”) device, a resistive random access memory (“ReRAM”) device, an electrically erasable programmable read-only memory (“EEPROM”) device, a flash memory (which may also be considered a subset of EEPROM) device, a ferroelectric random access memory (“FRAM”) device, a magnetoresistive random access memory (“MRAM”) device, and a nonvolatile memory device such as other semiconductor devices capable of storing information.

According to an embodiment, the electronic device may be a DRAM device.

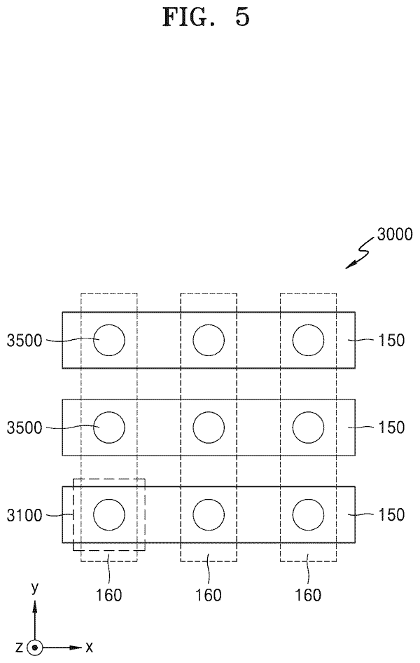

Hereinafter, the manufacturing method of the electronic device will be described in more detail with reference to FIGS. 5, 6A, 6B, 7, 8 and 9.

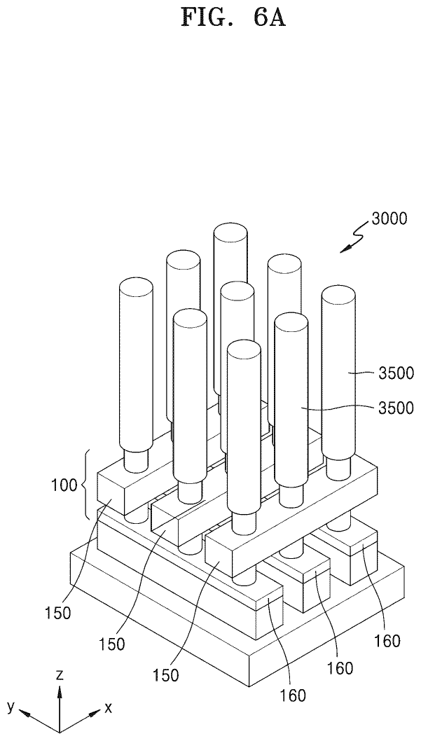

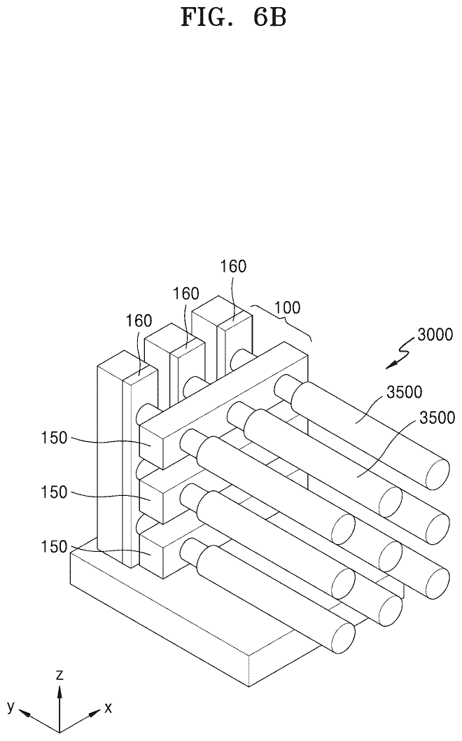

FIG. 5 is a schematic plan view of an electronic device 3000 according to an embodiment, and FIGS. 6A and 6B are perspective views of the electronic device 3000 shown in FIG. 5. The electronic device 3000 of FIG. 5 may be a DRAM device.

Referring to FIGS. 5, 6A and 6B, the electronic device 3000 includes a plurality of unit elements 3100 arranged in an array form. Each unit element 3100 has a 1T1C structure including (or consisting of) one transistor and one capacitor.

The electronic device 3000 includes a transistor structure 100 and a plurality of capacitors 3500 provided to the transistor structure 100. The transistor structure 100 may be, for example, a vertical channel array transistor structure including channels arranged vertically with respect to the substrate (see FIG. 6A), or a channel array transistor structure including channels arranged and stacked horizontally with respect to the substrate (see FIG. 6B).

In the transistor structure 100, a plurality of gate electrodes (or word lines) 150 and a plurality of bit lines 160 are provided to intersect each other. Each gate electrode 150 may be provided to extend in a first direction (for example, the x-axis direction), and each bit line 160 may be provided to extend in a second direction (for example, the y-axis direction) intersecting the first direction. Transistors are arranged at points where the plurality of gate electrodes 150 and the plurality of bit lines 160 intersect.

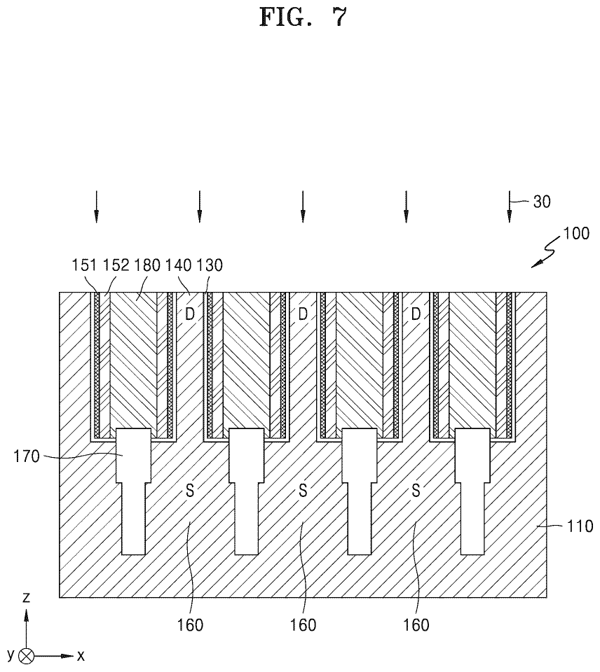

FIGS. 7 to 9 are views schematically illustrating part of the manufacturing process of the transistor structure 100 illustrated in FIG. 6A.

In FIG. 7, the transistor structure 100 includes a substrate 110 and a plurality of channels 140 arranged in an array form on the substrate 110. The plurality of channels 140 may be arranged in a two-dimensional array form on a plane (for example, xy-plane) of the substrate 110.

The substrate 110 may include a semiconductor, for example, silicon (Si). As a specific example, the substrate 110 may be a silicon substrate doped with an n-type impurity. However, this is merely illustrative. Alternatively, the substrate 110 may include, for example, a Group IV semiconductor material such as germanium (Ge), silicon-germanium (SiGe), or silicon carbide (SiC); a Group III-V semiconductor material such as gallium arsenide (GaAs), indium arsenide (InAs), or indium phosphide (InP); or an oxide semiconductor, nitride semiconductor, oxynitride semiconductor or the like.

Each of the plurality of channels 140 may be provided to extend vertically from the substrate 110. Each channel 140 may be provided to protrude vertically from the upper surface of the substrate 110. Each channel 140 may be formed integrally with the substrate 110 and thus may include the same semiconductor material as the semiconductor substrate 110. In FIG. 7, the channels 140 are shown formed integrally with the substrate 110, but various modifications are possible, such as the channel 140 being formed separately from the substrate 110.

A source(S) and a drain (D) are provided at the bottom and top of each channel 140, respectively. The source(S) is provided to be electrically connected to the bottom of the channel 140, and the drain (D) is provided to be connected to the top of the channel 140. For example, the source(S) and drain (D) may be formed through the formation of a doped region. The capacitor 3500 illustrated in FIG. 5 may be connected to a drain (D) provided at the upper portion of the channel 140.

On the top surface of the substrate 110, sources(S) are provided in an array form corresponding to channels 140. Beneath the sources(S), a plurality of bit lines 160 are provided to extend along a second direction (for example, the y-axis direction). Each bit line 160 may electrically connect the sources(S) arranged along the second direction. The plurality of bit lines 160 may be formed within the substrate 110 and thus may include the same semiconductor material as the substrate 110. In FIG. 7, the bit lines 160 are formed using a material separate from the substrate 110; however, various modifications are possible.

A plurality of insulating materials 170 may be provided in the substrate 110 between the bit lines 160. The plurality of insulating materials 170 may be provided to extend along the second direction, in parallel with the plurality of bit lines 160, thereby separating the plurality of bit lines 160 within the substrate 110. The insulating material 170 may include, for example, silicon oxide, silicon nitride, silicon oxynitride, aluminum oxide, hafnium oxide, hafnium oxynitride, zirconium oxide, or a combination thereof.

A gate insulating film 130 is provided on the surface of the channels 140. The gate insulating film 130 may include an insulating material as described herein, for example, silicon oxide, silicon nitride, silicon oxynitride, aluminum oxide, hafnium oxide, hafnium oxynitride, zirconium oxide, or a combination thereof.

In the substrate 110 provided with the channels 140 and the gate insulating film 130 as described above, a barrier layer 151 including a metal nitride, a metal oxynitride, or a combination thereof, and a conductive layer 152 including a conductive metal, are provided in a trench defined at least in part by the gate insulating film 130, as illustrated in FIG. 7. For example, after forming the barrier layer 151, the conductive layer 152 may be formed on the surface of the barrier layer 151. However, depending on the structure of the channels 140 and/or gate electrode 150, various modifications are possible, such as forming the barrier layer 151 on the surface of the conductive layer 152 after the conductive layer 152 is formed. For a description of the metal nitride and/or metal oxynitride included in the barrier layer 151, and of the conductive metal included in the conductive layer 152, reference is made to the descriptions herein.

Subsequently, as illustrated in FIG. 7, an embedded insulating layer 180 is provided within a trench at least partially defined by the conductive layer 152. The embedded insulating layer 180 may serve to protect the gate electrode 150 of FIG. 8 from the penetration of oxygen and the like. After forming the embedded insulating layer 180, a planarization process may additionally be performed so that the top surfaces of the barrier layer 151 and the conductive layer 152 are exposed.

Then, the exposed top surfaces of the barrier layer 151 and the conductive layer 152 are brought into contact with the composition 30 to etch a portion of the barrier layer 151 and a portion of the conductive layer 152, thereby forming the gate electrode 150 having the pattern shown in FIG. 8. The composition 30 in FIG. 7 includes the oxidizing agent, the phosphoric acid, the organic acid, and the etching controller as described in this specification, and for a detailed description thereof, reference is made to the descriptions herein.

An etching rate ratio, which is obtained by dividing a first etching rate at which the composition 30 etches the barrier layer 151 by a second etching rate at which the composition 30 etches the conductive layer 152, may be 0.04 or more. For example, the etching rate ratio, which is obtained by dividing the first etching rate at which the composition 30 etches the barrier layer 151 by the second etching rate at which the composition 30 etches the conductive layer 152, may be 0.05 or more, about 0.06 or more, about 0.04 to about 1.0, about 0.05 to about 1.0, about 0.06 to about 1.0, about 0.04 to about 0.5, about 0.05 to about 0.5, about 0.06 to about 0.5, about 0.04 to about 0.3, about 0.05 to about 0.3, about 0.06 to about 0.3, about 0.04 to about 0.2, about 0.05 to about 0.2, about 0.06 to about 0.2, about 0.04 to about 0.15, about 0.05 to about 0.15, about 0.06 to about 0.15, or about 0.06 to about 0.13.

Meanwhile, an etching area ratio, which is obtained by dividing a first area of the barrier layer 151 exposed for contact with the composition 30 by a second area of the conductive layer 152 exposed for contact with the composition 30, may be about 0.05 to about 1.0, about 0.05 to about 0.9, about 0.05 to about 0.7, about 0.05 to about 0.5, about 0.05 to about 0.4, about 0.05 to about 0.3, or about 0.05 to about 0.2.

When the barrier layer 151 and the conductive layer 152 come into contact with the composition 30, the higher reactivity of the conductive metal included in the conductive layer 152 may be controlled through the interaction among the oxidizing agent, the phosphoric acid, the organic acid, and the etching controller included in the composition 30. As a result, the etch rate of the conductive layer 152 may be appropriately controlled, and portions of both the barrier layer 151 and the conductive layer 152 may be etched. Accordingly, as illustrated in FIG. 8, a gate electrode 150 having a substantially planar top surface (for example, with little or no step height difference between the barrier layer 151 and the conductive layer 152) may be formed. Furthermore, after the contact process with the composition 30, various by-products derived from the conductive layer 152 (for example, oxides of the conductive metal) may be substantially absent from the surface of the gate electrode 150. In addition, the channel 140, the gate insulating film 130, and the embedded insulating layer 180 arranged adjacent to the gate electrode 150 may be substantially undamaged by the composition 30, so that a high-quality electronic device 3000 including a gate electrode 150 having a precise pattern may be manufactured without damage to an area adjacent to the gate electrode 150, for example, the channel 140, the gate insulating film 130, and the embedded insulating layer 180.

In FIG. 8, the plurality of gate electrodes 150 on the substrate 110 may be arranged to extend along a first direction (for example, the x-axis direction). The first direction may be a direction intersecting with the second direction described above. For example, the first direction may be a direction perpendicular to the second direction. However, it is not necessarily limited thereto.

Each gate electrode 150 is provided to correspond to the channels 140 arranged along the first direction. Specifically, each gate electrode 150 may be provided to surround the channels 140 arranged along the first direction. These gate electrodes 150 may function as word lines.

The plurality of gate electrodes 150 may be provided to intersect with a plurality of insulating materials 170 provided thereunder. The top surface of the insulating materials 170 may be provided so as to be adjacent to the bottom surface of the gate electrodes 150. The top of the insulating materials 170 may be provided to protrude from the bottom of the gate electrodes 150, but is not limited thereto.

Subsequently, as shown in FIG. 9, an insulating layer 190 may be additionally provided on the surface of the etched barrier layer 151 and the surface of the etched conductive layer 152. The insulating layer 190 may serve to further insulate the gate electrode 150 from the channel 140, and may include, for example, an insulating material as described herein.

### Method of Manufacturing an Electronic Apparatus

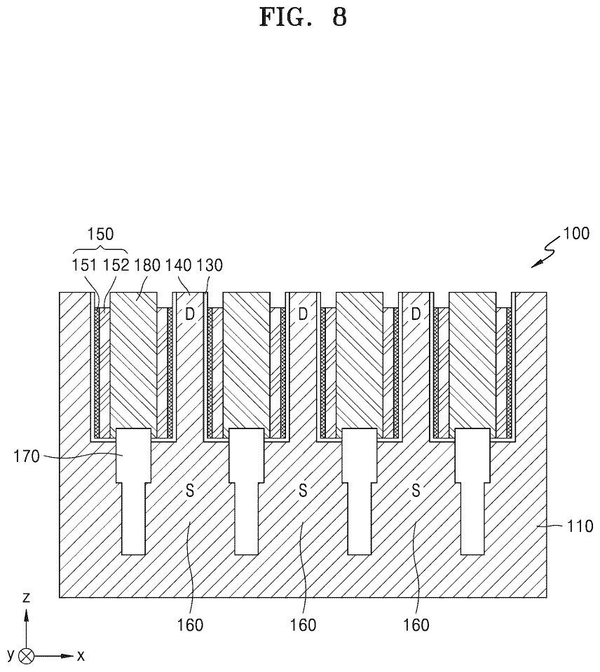

Referring to FIG. 10, an embodiment of a method of manufacturing an electronic apparatus may include: preparing a substrate on which is provided a metal-containing film (S100); bringing the metal-containing film into contact with a composition as described herein (S110); and manufacturing the electronic element using one or more subsequent processes (S120). The subsequent processes may include various known processes for manufacturing electronic elements, such as a capacitor formation process.

### Example 1 and Comparative Examples C1, C2 and C21

Substances listed in Table 1 as an oxidizing agent, an inorganic acid, an organic acid, and an etching controller were mixed according to the amounts described in Table 1 to thereby manufacture compositions of Example 1 and Comparative Examples C1, C2 and C21. The remainder of each composition may correspond to water (deionized water).

### Evaluation Example 1

The composition of Example 1 was placed in each of three beakers and heated to 60° C., and then, titanium nitride-containing film, molybdenum film, and silicon oxide film specimens, each having a size of 1 cm×1 cm, were immersed in each of the beakers for 1 minute. Then, the thicknesses of the titanium nitride-containing film, the molybdenum film, and the silicon oxide film were measured by using an ellipsometer (M-2000, J. A. Woolam), a four-point resistance meter, and X-ray fluorescence spectroscopy (XRF) to evaluate the rate at which the composition of Example 1 etches the titanium nitride-containing film (also referred to as the “titanium nitride-containing film etching rate”), the rate at which the composition of Example 1 etches the molybdenum film (also referred to as the “molybdenum film etching rate”), an etching rate ratio R obtained by dividing the titanium nitride-containing film etching rate by the molybdenum film etching rate, and the rate at which the composition of Example 1 etches the silicon oxide film (also referred to as the “silicon oxide film etching rate”). The results are summarized in Table 1 together with the pH of Example 1. The unit of each etching rate is “Å/min.”

The tests were repeated using each of the compositions of Comparative Examples C1 and C2, and the results are summarized in Table 1.

Also, for the composition of Comparative Example C21, to perform the evaluation in the same manner as in Evaluation Example 1, the composition of Comparative Example C21 was placed in a beaker and heated to 60° C. However, brown gas was generated in the beaker during heating, and therefore, it was not possible to evaluate the titanium nitride-containing film etching rate of Comparative Example C21, the molybdenum film etching rate of Comparative Example C21, and silicon oxide film etching rate of Comparative Example C21.

In Tables 1 to 5, “-” indicates “no evaluation value.” Specifically, in Tables 1 to 5, the etching rate indicated as “-” indicates that the etching rate is so small that it cannot be measured, and thus, almost no etching occurs.

TABLE 1

| | | | | | | Titanium | | | |
|---|---|---|---|---|---|---|---|---|---|
| | | | | | | nitride- | Molyb- | | Silicon |
| | | | | | | contain- | denum | | oxide |
| | | | | | | ing film | film | Etching | film |
| | | | | | | etching | etching | Rate | etching |
| | Oxidizing | Inorganic | Organic | Etching | | rate | rate | Ratio | rate |
| | agent | acid | acid | controller | pH | (Å/min) | (Å/min) | (R) | (Å/min) |
| Exam- | Hydrogen | Phos- | Acetic | A1 | −0.4 | 2.1 | 23.3 | 0.09 | <1 |
| ple | peroxide | phoric | acid | (1 | | | | | |
| 1 | (0.5 wt %) | acid (60 | (10 | wt %) | | | | | |
| | | wt %) | wt %) | | | | | | |
| Com- | — | Phos- | Acetic | A1 | −0.4 | <1 | <1 | — | — |
| parative | | phoric | acid | (1 | | | | | |
| Exam- | | acid (60 | (10 | wt %) | | | | | |
| ple | | wt %) | wt %) | | | | | | |
| C1 | | | | | | | | | |
| Com- | HF | Phos- | Acetic | A1 | −0.4 | <1 | <1 | — | >30 |
| parative | (0.02 wt %) | phoric | acid | (1 | | | | | |
| Exam- | | acid (60 | (10 | wt %) | | | | | |
| ple C2 | | wt %) | wt %) | | | | | | |

| | | | | | | |
|---|---|---|---|---|---|---|
| Com- | Nitric acid | Phos- | Acetic | A1 | — | Not Evaluable |
| parative | (4.8 wt %) | phoric | acid | (4 | | |
| Exam- | | acid (70 | (10 | wt %) | | |
| ple | | wt %) | wt %) | | | |
| C21 | | | | | | |

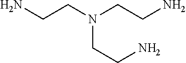

A1

From Table 1, it can be confirmed that i) the composition of Comparative Example C1 not including an oxidizing agent substantially does not etch the titanium nitride-containing film and the molybdenum film, and ii) the composition of Comparative Example C2 including HF (hydrofluoric acid) as an oxidizing agent substantially does not etch the titanium nitride-containing film and the molybdenum film, and also damages the silicon oxide film. On the other hand, it can be confirmed that the composition of Example 1 can simultaneously etch both the titanium nitride-containing film and the molybdenum film at a more appropriate etching ratio without substantially damaging the silicon oxide film, and thus can be usefully used for more uniform etching of metal-containing films having various compositions.

Meanwhile, it can be confirmed that the composition of Comparative Example C21 does not have stability sufficient to be effectively used in the treatment of metal-containing films having various compositions.

### Comparative Examples C3 to C5 and C31

Substances which were listed in Table 2 as an oxidizing agent, an inorganic acid, an organic acid, and an etching controller were mixed according to the amounts described in Table 2 to thereby manufacture compositions of Comparative Examples C3 to C5 and C31. The remainder of each composition corresponds to water (deionized water).

### Evaluation Example 2

For the composition of Comparative Example C3, the pH, molybdenum film etching rate, and silicon oxide film etching rate were evaluated according to the method described in Evaluation Example 1, and the results are summarized in Table 2. For comparison, the pH, molybdenum film etching rate, and silicon oxide film etching rate of the composition of Example 1 are also shown in Table 2.

The tests were repeated using the composition of Comparative Example C31, and the results are summarized in Table 2.

Meanwhile, for the compositions of Comparative Examples C4 and C5, to perform the evaluation in the same manner as in Evaluation Example 1, the compositions of Comparative Examples C4 and C5 were each placed in a beaker and heated to 60° C. However, gas was generated in the beaker during heating, and therefore, it was not possible to evaluate the molybdenum film etching rate and silicon oxide film etching rate of Comparative Examples C4 and C5.

TABLE 2

| | | | | | | Molybdenum | Silicon oxide |
|---|---|---|---|---|---|---|---|
| | | | | | | film | film |
| | Oxidizing | Inorganic | Organic | Etching | | etching rate | etching rate |
| | agent | acid | acid | controller | pH | (Å/min) | (Å/min) |
| Example 1 | Hydrogen | Phosphoric | Acetic | A1 | −0.4 | 23.3 | <1 |
| | peroxide | acid | acid | (1 wt %) | | | |
| | (0.5 wt %) | (60 wt %) | (10 wt %) | | | | |
| Comparative | Hydrogen | — | Acetic | A1 | 2.3 | 67 | — |
| Example C3 | peroxide | | acid | (1 wt %) | | | |
| | (0.5 wt %) | | (10 wt %) | | | | |
| Comparative | Hydrogen | Sulfuric | Acetic | A1 | — | Not Evaluable | |
| Example C4 | peroxide | acid | acid | (1 wt %) | | | |
| | (4 wt %) | (10 wt %) | (10 wt %) | | | | |
| Comparative | Hydrogen | Hydrochloric | Acetic | A1 | — | | |
| Example C5 | peroxide | acid | acid | (1 wt %) | | | |
| | (4 wt %) | (10 wt %) | (10 wt %) | | | | |
| Comparative | Hydrogen | Nitric | Acetic | A1 | 2.5 | 120 | <1 |
| Example C31 | peroxide | acid | acid | (1 wt %) | | | |
| | (0.5 wt %) | (1 wt %) | (10 wt %) | | | | |

From Table 2, it can be confirmed that the molybdenum film etching rate of the compositions of Comparative Examples C3 and C31 not including phosphoric acid are greater than the molybdenum film etching rate of the composition of Example 1. From this, it can be confirmed that the composition of Example 1 can etch a molybdenum film at a more appropriate etching rate without substantially damaging a silicon oxide film, compared to the compositions of Comparative Examples C3 and C31, and thus can be usefully used for more uniform etching of metal-containing films having various compositions.

Meanwhile, it can be confirmed that the compositions of Comparative Examples C4 and C5 do not have stability sufficient to be effectively used in the treatment of metal-containing films having various compositions.

### Comparative Example C6

Substances which were listed in Table 3 as an oxidizing agent, an inorganic acid, an organic acid, and an etching controller were mixed according to the amounts described in Table 3 to thereby manufacture a composition of Comparative Example C6. The remainder of the composition corresponds to water (deionized water).

### Evaluation Example 3

For the composition of Comparative Example C6, the pH, molybdenum film etching rate, and silicon oxide film etching rate were evaluated according to the method described in Evaluation Example 1, and the results are summarized in Table 3. For comparison, the pH, molybdenum film etching rate, and silicon oxide film etching rate of the composition of Example 1 are also shown in Table 3.

TABLE 3

| | | | | | | Molybdenum | Silicon oxide |
|---|---|---|---|---|---|---|---|
| | | | | | | film | film |
| | Oxidizing | Inorganic | Organic | Etching | | etching rate | etching rate |
| | agent | acid | acid | controller | pH | (Å/min) | (Å/min) |
| Example 1 | Hydrogen | Phosphoric | Acetic | A1 | −0.4 | 23.3 | <1 |
| | peroxide | acid | acid | (1 wt %) | | | |
| | (0.5 wt %) | (60 wt %) | (10 wt %) | | | | |
| Comparative | Hydrogen | Phosphoric | — | A1 | −0.4 | 87.2 | — |
| Example C6 | peroxide | acid | | (1 wt %) | | | |
| | (0.5 wt %) | (60 wt %) | | | | | |

From Table 3, it can be confirmed that the molybdenum film etching rate of the composition of Comparative Example C6 not including acetic acid is greater than the molybdenum film etching rate of the composition of Example 1. From this, it can be confirmed that the composition of Example 1 can etch a molybdenum film at a more appropriate etching rate compared to the composition of Comparative Example C6, and thus can be usefully used for more uniform etching of metal-containing films having various compositions.

### Comparative Examples C7 to C12

Substances which were listed in Table 4 as an oxidizing agent, an inorganic acid, an organic acid, and an etching controller were mixed according to the amounts described in Table 4 to thereby manufacture compositions of Comparative Examples C7 to C12. The remainder of each composition corresponds to water (deionized water).

### Evaluation Example 4

For each of the compositions of Comparative Examples C7 to C12, the pH, molybdenum film etching rate, and silicon oxide film etching rate were evaluated according to the method described in Evaluation Example 1, and the results are summarized in Table 4. For comparison, the pH, molybdenum film etching rate, and silicon oxide film etching rate of the composition of Example 1 are also shown in Table 4.

TABLE 4

| | | | | | | Molybdenum | Silicon oxide |
|---|---|---|---|---|---|---|---|
| | | | | | | film | film etching |
| | Oxidizing | Inorganic | Organic | Etching | | etching rate | rate |
| | agent | acid | acid | controller | pH | (Å/min) | (Å/min) |
| Exam- | Hydrogen | Phos- | Acetic | A1 | −0.4 | 23.3 | <1 |
| ple | peroxide | phoric | acid | (1 | | | |
| 1 | (0.5 wt %) | acid (60 | (10 | wt %) | | | |
| | | wt %) | wt %) | | | | |
| Com- | Hydrogen | Phos- | Acetic | — | −0.6 | 237.2 | — |
| parative | peroxide | phoric | acid | | | | |
| Exam- | (0.5 wt %) | acid (60 | (10 | | | | |
| ple | | wt %) | wt %) | | | | |
| C7 | | | | | | | |
| Com- | Hydrogen | Phosph | Acetic | Ref1 | −0.3 | 105.5 | <1 |
| parative | peroxide | oric acid | acid | (1 | | | |
| Exam- | (0.5 wt %) | (60 | (10 | wt %) | | | |
| ple C8 | | wt %) | wt %) | | | | |
| Com- | Hydrogen | Phos- | Acetic | Ref2 | −0.4 | 170 | — |
| parative | peroxide | phoric | acid | (1 | | | |
| Exam- | (0.5 wt %) | acid (60 | (10 | wt %) | | | |
| ple C9 | | wt %) | wt %) | | | | |
| Com- | Hydrogen | Phos- | Acetic | Ref3 | −0.7 | 180 | — |
| parative | peroxide | phoric | acid | (1 | | | |
| Exam- | (0.5 wt %) | acid (60 | (10 | wt %) | | | |
| ple C10 | | wt %) | wt %) | | | | |
| Com- | Hydrogen | Phos- | Acetic | Ref4 | −0.5 | 165 | — |
| parative | peroxide | phoric | acid | (1 | | | |
| Exam- | (0.5 wt %) | acid (60 | (10 | wt %) | | | |
| ple C11 | | wt %) | wt %) | | | | |
| Com- | Hydrogen | Phos- | Acetic | Ref5 | −0.3 | 173 | — |
| parative | peroxide | phoric | acid | (1 | | | |
| Exam- | (0.5 wt %) | acid (60 | (10 | wt %) | | | |
| ple C12 | | wt %) | wt %) | | | | |

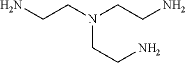

A1 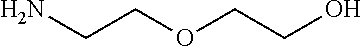
Ref1 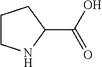
Ref2 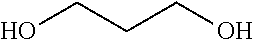
Ref3 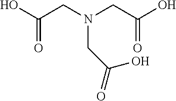 [SMILES: O=C(O)CN(CC(=O)O)CC(=O)O]
Ref4 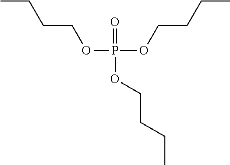 [SMILES: CCCCOP(=O)(OCCCC)OCCCC]
Ref5

From Table 4, it can be confirmed that the molybdenum film etching rates of the composition of Comparative Example C7 not including an etching controller, the compositions of Comparative Examples C8 to C11 including a hydroxyl-containing and nitrogen-containing compound as an etching controller, and the composition of Comparative Example C12 including a nitrogen-free compound as an etching controller are each greater than the molybdenum film etching rate of the composition of Example 1. From this, it can be confirmed that the composition of Example 1 can etch a molybdenum film at a more appropriate etching rate compared to each of the compositions of Comparative Examples C7 to C12, and thus can be usefully used for more uniform etching of metal-containing films having various compositions.

### Examples 2 to 4

Substances which were listed in Table 5 as an oxidizing agent, an inorganic acid, an organic acid, and an etching controller were mixed according to the amounts described in Table 5 to thereby manufacture the compositions of Examples 2 to 4. The remainder of each composition corresponds to water (deionized water).

### Evaluation Example 5

For each of the compositions of Examples 2 to 4, the pH, titanium nitride-containing film etching rate, molybdenum film etching rate, R, and silicon oxide film etching rate were evaluated according to the method described in Evaluation Example 1, and the results are summarized in Table 5. The pH, titanium nitride-containing film etching rate, molybdenum film etching rate, R, and silicon oxide film etching rate of the composition of Example 1 are also shown in Table 5.

TABLE 5

| | | | | | | Titanium | | | |
|---|---|---|---|---|---|---|---|---|---|
| | | | | | | nitride- | | | Silicon |
| | | | | | | contain- | Molybdenum | | oxide |
| | | | | | | ing film | film | Etching | film |
| | | | | | | etching | etching | Rate | etching |
| | Oxidizing | Inorganic | Organic | Etching | | rate | rate | Ratio | rate |
| | agent | acid | acid | controller | pH | (Å/min) | (Å/min) | (R) | (Å/min) |
| Exam- | Hydrogen | Phos- | Acetic | A1 | −0.4 | 2.1 | 23.3 | 0.09 | <1 |
| ple | peroxide | phoric | acid | (1 | | | | | |
| 1 | (0.5 wt %) | acid (60 | (10 | wt %) | | | | | |
| | | wt %) | wt %) | | | | | | |
| Exam- | Hydrogen | Phos- | Propionic | A1 | −0.4 | 3.4 | 26.5 | 0.13 | — |
| ple | peroxide | phoric | acid | (1 | | | | | |
| 2 | (0.5 wt %) | acid (60 | (10 | wt %) | | | | | |
| | | wt %) | wt %) | | | | | | |
| Exam- | Hydrogen | Phos- | Acetic | A5 | −0.4 | 2.8 | 48.3 | 0.06 | <1 |
| ple | peroxide | phoric | acid | (1 | | | | | |
| 3 | (0.5 wt %) | acid (60 | (10 | wt %) | | | | | |
| | | wt %) | wt %) | | | | | | |
| Exam- | Periodic | Phos- | Acetic | A1 | −0.4 | 1.8 | 19.8 | 0.09 | <1 |
| ple | acid (HIO₄) | phoric | acid | (1 | | | | | |
| 4 | (0.02 wt %) | acid (60 | (10 | wt %) | | | | | |
| | | wt %) | wt %) | | | | | | |

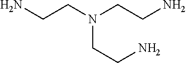

A1 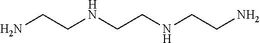
A5

From Table 5, it can be confirmed that the compositions of Examples 2 to 4 can simultaneously etch both the titanium nitride-containing film and the molybdenum film at a more appropriate etching ratio without substantially damaging the silicon oxide film, comparable to the composition of Example 1, and thus can be usefully used for more uniform etching of metal-containing films having various compositions.

### Example 5 and Comparative Example C41

Substances which were listed in Table 6 as an oxidizing agent, an inorganic acid, an organic acid, and an etching controller were mixed according to the amounts described in Table 6 to thereby manufacture the compositions of Example 5 and Comparative Example C41. The remainder of each composition corresponds to water (deionized water). The weight average molecular weight of polyethyleneimine (PEI) used as an etching controller in Comparative Example C41 is 800 g/mol (n is an integer satisfying the weight average molecular weight), and the amount of PEI in Table 6 indicates an amount of the solid component of PEI.

### Evaluation Example 6

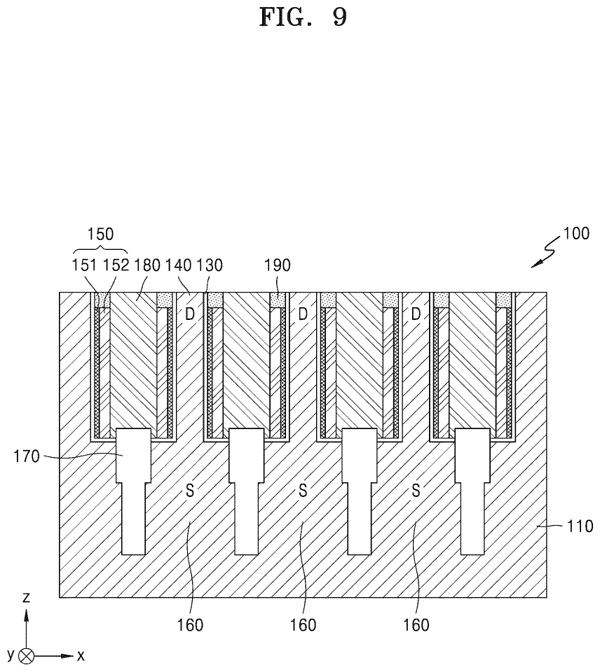

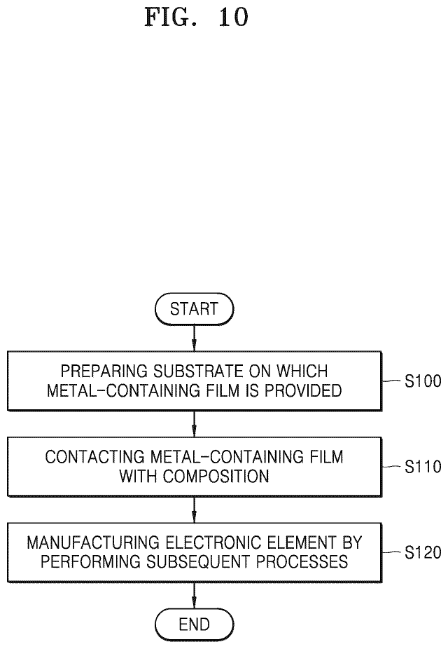

The compositions of Example 5 and Comparative Example C41 were placed in two beakers respectively and heated to 60° C. Then, 1H NMR analysis was performed on the composition of each beaker to evaluate whether the structures of Compound A1 and PEI were modified after mixing with high-concentration (70 wt %) phosphoric acid and heating at high temperature (60° C.). The results are summarized in Table 6. In addition, the 1H NMR data of Compound A1 after mixing with high-concentration (70 wt %) phosphoric acid and heating at high temperature (60° C.) are shown in FIG. 11A, and the 1H NMR data of PEI after mixing with high-concentration (70 wt %) phosphoric acid and heating at high temperature (60° C.) are shown in FIG. 11B.

TABLE 6

| | | | | | Structural |
|---|---|---|---|---|---|
| | | | | | modification of |
| | | | | | etching controller |
| | | | | | after mixing with |
| | | | | | high-concentration |
| | | | | | (70 wt %) phosphoric |
| | | | | | acid and heating at |
| | Oxidizing | Inorganic | Organic | Etching | high temperature |
| | agent | acid | acid | controller | (60° C.) |
| Example | Hydrogen | Phosphoric | Acetic | A1 | X |
| 5 | peroxide | acid | acid | (1 wt %) | |
| | (0.5 wt %) | (70 wt %) | (10 | | |
| | | | wt %) | | |
| Comparative | Hydrogen | Phosphoric | Acetic | PEI | O |
| Example | peroxide | acid | acid | (1 wt %) | |
| C41 | (0.5 wt %) | (70 wt %) | (10 | | |
| | | | wt %) | | |

X: In 1H NMR, peaks corresponding to amine oxides and/or amides, which are structural modification products of the amine-containing etching controller, are barely observed.
O: In 1H NMR, many peaks corresponding to amine oxides and/or amides, which are structural modification products of the amine-containing etching controller, are observed. 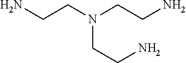
A1 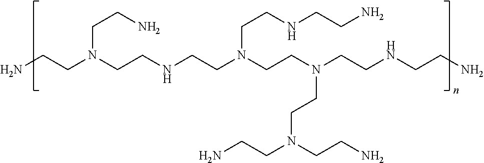
PEI

From FIG. 6, FIG. 11A, and FIG. 11B, it was confirmed that the structure of Compound A1 was substantially not modified after mixing with high-concentration (70 wt %) phosphoric acid and heating at high temperature (60° C.), but the structure of PEI was modified after mixing with high-concentration (70 wt %) phosphoric acid and heating at high temperature (60° C.). Therefore, it was confirmed that Compound A1 can be stably used even under the conditions of mixing with high-concentration (70 wt %) phosphoric acid and heating at high temperature (60° C.), but PEI cannot be stably used under the conditions of mixing with high-concentration (70 wt %) phosphoric acid and heating at high temperature (60° C.).

### Evaluation Example 7

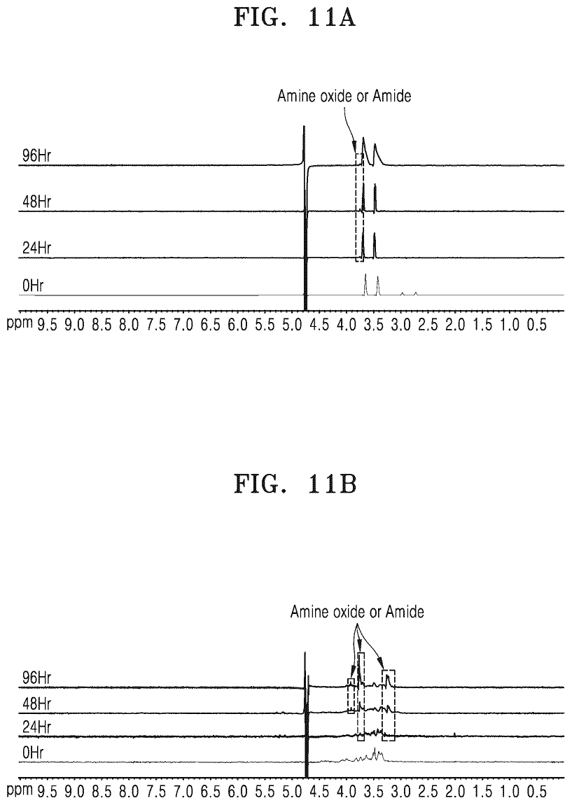

Two of Sample 1 having a size of 1 cm×1 cm were prepared, each of which had a molybdenum film (see “M” region in FIG. 12) and a titanium nitride-containing film (see “T” region in FIG. 12) arranged between two silicon oxide films (see “S1” region and “S2” region in FIG. 12). FIG. 12 is a transmission electron microscope (TEM) image of Sample 1.

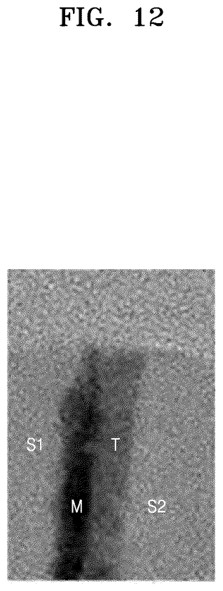

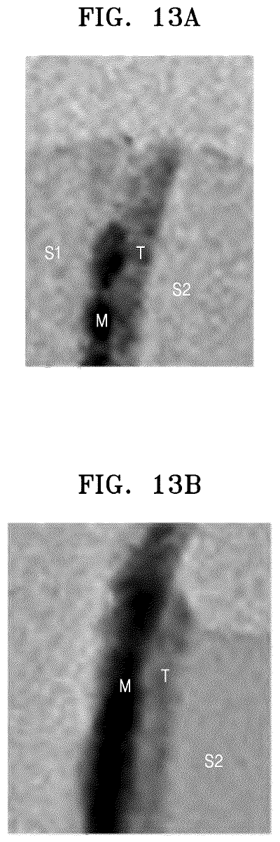

Subsequently, the compositions of Example 1 (using hydrogen peroxide as an oxidizing agent) and Comparative Example C2 (using HF as an oxidizing agent) were placed in two beakers respectively and heated to 60° C., and then Sample 1 was immersed in each of the beakers for 10 minutes, rinsed with deionized water, and dried to obtain Sample 1 immersed in each of the compositions. A TEM image of Sample 1 immersed in the composition of Example 1 obtained therefrom is shown in FIG. 13A, and a TEM image of Sample 1 immersed in the composition of Comparative Example C2 is shown in FIG. 13B.

It can be confirmed that in FIG. 13A in which a TEM image of Sample 1 immersed in the composition of Example 1 is shown, both the “S1” region and the “S2” region as two silicon oxide films are observed, but in FIG. 13B in which a TEM image of Sample 1 immersed in the composition of Comparative Example C2 is shown, the “S1” region as the silicon oxide film on the left is not observed, and a significant amount of the “S2” region as the silicon oxide film on the right has also been lost.

From this, it can be confirmed that the composition of Example 1, unlike the composition of Comparative Example C2, can be usefully used for treating various metal-containing films without substantial damage to the silicon oxide film adjacent to the metal-containing film.

The composition can be more effectively used in various treatment processes for the metal-containing film, such as etching, cleaning, and polishing processes, since it is easier to control the etching rate for various metal-containing films. Thus, by treating a metal-containing film using the composition, higher-quality electronic devices and semiconductor devices can be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of treating a metal-containing film, comprising:
preparing a substrate including the metal-containing film, the metal-containing film including a first region and a second region; and
contacting the metal-containing film with a composition;
wherein the first region and the second region independently comprise titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof,
wherein a material included in the first region is different from a material included in the second region,
wherein the composition comprises an oxidizing agent, a phosphoric acid, an organic acid, and an etching controller,
wherein the oxidizing agent comprises hydrogen peroxide, an iodine-containing compound, or any combination thereof,
wherein the etching controller comprises a hydroxyl-free and nitrogen-containing compound,
wherein the hydroxyl-free and nitrogen-containing compound comprises a compound represented by Formula 5, a compound represented by Formula 6, or any combination thereof, and
wherein the composition has a pH of 2 or less, 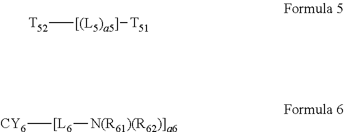
wherein, in Formula 5, L₅ is *—C(Z₅₁) (Z₅₂)—*′, *—N(Z₅₃)—*′, or *—C(═O)—*′,
in Formula 5, a5 is an integer from 2 to 30,
in Formula 5, T₅₁ is *—N(R₅₁) (R₅₂), and T₅₂ is *—N(R₅₃) (R₅₄),
in Formula 6, ring CY₆ is a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, L₆ is a single bond or a C₁-C₃₀ alkylene group,
in Formula 6, a6 is an integer from 1 to 5,
in Formulae 5 and 6, Z₅₁, Z₅₂, Z₅₃, R₅₁, R₅₂, R₅₃, R₅₄, R₆₁, and R₆₂ are each independently:
hydrogen or an amino group; or
a C₁-C₃₀ alkyl group which is unsubstituted or substituted with an amino group, a mono(C₁-C₃₀ alkyl)amino group, a di(C₁-C₃₀ alkyl)amino group, *—C(═O)—N(Q₅₁) (Q₅₂), or any combination thereof,
Q₅₁ and Q₅₂ are each independently:
hydrogen; or
a C₁-C₃₀ alkyl group which is unsubstituted or substituted with an amino group, a mono(C₁-C₃₀ alkyl)amino group, a di(C₁-C₃₀ alkyl)amino group, or any combination thereof, and
* and *′ each indicate a binding site to a neighboring atom.

2. The method of claim 1,
wherein the first region comprises titanium (Ti), indium (In), aluminum (Al), lanthanum (La), scandium (Sc), gallium (Ga), or any combination thereof, and
the second region comprises tungsten (W), molybdenum (Mo), ruthenium (Ru), or any combination thereof.

3. The method of claim 1,
wherein the first region comprises a metal nitride, a metal oxynitride, or any combination thereof, and
the second region comprises a conductive metal.

4. The method of claim 1,
wherein the first region comprises a titanium nitride, a titanium oxynitride, or any combination thereof and each of the titanium nitride and the titanium oxynitride optionally further comprises indium (In), aluminum (Al), lanthanum (La), scandium (Sc), gallium (Ga), silicon (Si), or any combination thereof.

5. The method of claim 1,
wherein an etching area ratio, which is a ratio obtained by dividing a first area of the first region exposed for contact with the composition by a second area of the second region exposed for contact with the composition, is in a range of about 0.05 to about 1.0.

6. The method of claim 1,
wherein an amount of the phosphoric acid in the composition is about 10 wt % to about 85 wt % based on 100 wt % of the composition.

7. The method of claim 1,
wherein, in Formula 5, i) each L₅ is *—C(Z₅₁) (Z₅₂)—*′ and a5 is an integer from 2 to 11, or ii) each L₅ is *—C(Z₅₁) (Z₅₂)—*′ or *—N(Z₅₃)—*′ and a5 is an integer from 5 to 11, and
in Formula 6, ring CY₆ is a cyclopentane group, a cyclohexane group, a cycloheptane group, a cyclooctane group, a cyclopentene group, a cyclohexene group, a cycloheptene group, a cyclooctene group, a benzene group, a naphthalene group, a piperazine group, a pyrrolidine group, a piperidine group, an azepane group, a tetrahydrofuran group, a tetrahydrothiophene group, a tetrahydro-2H-pyran group, a tetrahydro-2H-thiopyran group, a 4H-pyran-4-one group, a pyridine group, a pyrimidine group, a pyrazine group, a pyridazine group, a triazine group, a carbazole group, a dibenzofuran group, or a dibenzothiophene group.

8. The method of claim 1,
wherein the composition has a pH of about −3.0 to about 1.0.

9. A method of manufacturing an electronic device including a transistor,
the transistor comprising
a channel,
a source and a drain spaced apart from each other and electrically connected to the channel,
a gate electrode, and
a gate insulating film between the gate electrode and the channel, and
the method comprising:
providing a barrier layer comprising a metal nitride, a metal oxynitride, or any combination thereof;
providing a conductive layer including a conductive metal; and
forming the gate electrode by bringing the barrier layer and the conductive layer into contact with a composition to etch a portion of the barrier layer and a portion of the conductive layer;
wherein the composition comprises an oxidizing agent, a phosphoric acid, an organic acid, and an etching controller,
wherein the oxidizing agent comprises hydrogen peroxide, an iodine-containing compound, or any combination thereof,
wherein the etching controller comprises a hydroxyl-free and nitrogen-containing compound,
wherein the hydroxyl-free and nitrogen-containing compound comprises a compound represented by Formula 5, a compound represented by Formula 6, or any combination thereof, and
wherein the composition has a pH of 2 or less, 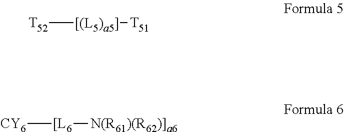
wherein, in Formula 5, L₅ is *—C(Z₅₁) (Z₅₂)—*′, *—N(Z₅₃)—*′, or *—C(═O)—*′,
in Formula 5, a5 is an integer from 2 to 30,
in Formula 5, T₅₁ is *—N(R₅₁) (R₅₂), and T₅₂ is *—N(R₅₃) (R₅₄),
in Formula 6, ring CY₆ is a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, L₆ is a single bond or a C₁-C₃₀ alkylene group,
in Formula 6, a6 is an integer from 1 to 5,
in Formulae 5 and 6, Z₅₁, Z₅₂, Z₅₃, R₅₁, R₅₂, R₅₃, R₅₄, R₆₁, and R₆₂ are each independently:
hydrogen or an amino group; or
a C₁-C₃₀ alkyl group which is unsubstituted or substituted with an amino group, a mono(C₁-C₃₀ alkyl)amino group, a di(C₁-C₃₀ alkyl)amino group, *—C(═O)—N(Q₅₁) (Q₅₂), or any combination thereof,
Q₅₁ and Q₅₂ are each independently:
hydrogen; or
a C₁-C₃₀ alkyl group which is unsubstituted or substituted with an amino group, a mono(C₁-C₃₀ alkyl)amino group, a di(C₁-C₃₀ alkyl)amino group, or any combination thereof, and
* and *′ each indicate a binding site to a neighboring atom.

10. The method of claim 9,
wherein the barrier layer comprises a titanium nitride, a titanium oxynitride, or any combination thereof,
each of the titanium nitride and the titanium oxynitride optionally further comprises indium (In), aluminum (Al), lanthanum (La), scandium (Sc), gallium (Ga), silicon (Si), or any combination thereof, and
the conductive layer comprises tungsten (W), molybdenum (Mo), ruthenium (Ru), or any combination thereof.

11. The method of claim 9, further comprising:
after the forming of the gate electrode by bringing the barrier layer and the conductive layer into contact with the composition to etch the portion of the barrier layer and the portion of the conductive layer, such that an etched barrier layer and an etched conductive layer are formed, providing an insulating layer on a surface of the etched barrier layer and a surface of the etched conductive layer.

12. A composition comprising:
an oxidizing agent;
a phosphoric acid; an organic acid; and
an etching controller,
wherein the oxidizing agent comprises hydrogen peroxide, an iodine-containing compound, or any combination thereof,
wherein the etching controller comprises a hydroxyl-free and nitrogen-containing compound,
wherein the hydroxyl-free and nitrogen-containing compound comprises a compound represented by Formula 5, a compound represented by Formula 6, or any combination thereof, and
wherein the composition has a pH of 2 or less, 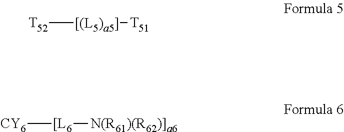
wherein, in Formula 5, L₅ is *—C(Z₅₁) (Z₅₂)—*′, *—N(Z₅₃)—*′, or *—C(═O)—*′,
in Formula 5, a5 is an integer from 2 to 30,
in Formula 5, T₅₁ is *—N(R₅₁) (R₅₂), and T₅₂ is *—N(R₅₃) (R₅₄),
in Formula 6, ring CY₆ is a saturated or unsaturated carbocyclic group having 5 to 15 carbon atoms, a saturated heterocyclic group having 2 to 15 carbon atoms, a pyridine group, a pyrimidine group, a pyrazine group, a pyridazine group, a triazine group, a carbazole group, a dibenzofuran group, or a dibenzothiophene group,
in Formula 6, Le is a single bond or a C₁-C₃₀ alkylene group,
in Formula 6, a6 is an integer from 1 to 5,
in Formulae 5 and 6, Z₅₁, Z₅₂, Z₅₃, R₅₁, R₅₂, R₅₃, R₅₄, R₆₁, and R₆₂ are each independently:
hydrogen or an amino group; or
a C₁-C₃₀ alkyl group which is unsubstituted or substituted with an amino group, a mono(C₁-C₃₀ alkyl)amino group, a di(C₁-C₃₀ alkyl)amino group, *—C(═O)—N(Q₅₁) (Q₅₂), or any combination thereof,
Q₅₁ and Q₅₂ are each independently:
hydrogen; or
a C₁-C₃₀ alkyl group which is unsubstituted or substituted with an amino group, a mono(C₁-C₃₀ alkyl)amino group, a di(C₁-C₃₀ alkyl)amino group, or any combination thereof, and
* and *′ each indicate a binding site to a neighboring atom.

13. The composition of claim 12,
wherein an amount of the oxidizing agent is about 0.001 wt % to about 3 wt % based on 100 wt % of the composition.

14. The composition of claim 12,
wherein an amount of the phosphoric acid is about 10 wt % to about 85 wt % based on 100 wt % of the composition.

15. The composition of claim 12,
wherein the organic acid comprises a monocarboxylic acid, a dicarboxylic acid, a tricarboxylic acid, or any combination thereof.

16. The composition of claim 12,
wherein the organic acid comprises formic acid, acetic acid, propionic acid, butyric acid, valeic acid, lauric acid, oxalic acid, malonic acid, glutaric acid, adipic acid, gallic acid, succinic acid, malic acid, maleic acid, crotonic acid, fumaric acid, ascorbic acid, glutamic acid, citric acid, tartaric acid, glycolic acid, lactic acid, benzoic acid, salicylic acid, or any combination thereof.

17. The composition of claim 12,
wherein an amount of the organic acid is about 0.1 wt % to about 15 wt % based on 100 wt % of the composition.

18. The composition of claim 12,
wherein, in Formula 5, i) each L₅ is *—C(Z₅₁) (Z₅₂)—*′ and a5 is an integer from 2 to 11, or ii) each L₅ is *—C(Z₅₁) (Z₅₂)—*′ or *—N(Z₅₃)—*′ and a5 is an integer from 5 to 11, and
in Formula 6, ring CY₆ is a cyclopentane group, a cyclohexane group, a cycloheptane group, a cyclooctane group, a cyclopentene group, a cyclohexene group, a cycloheptene group, a cyclooctene group, a benzene group, a naphthalene group, a piperazine group, a pyrrolidine group, a piperidine group, an azepane group, a tetrahydrofuran group, a tetrahydrothiophene group, a tetrahydro-2H-pyran group, a tetrahydro-2H-thiopyran group, a 4H-pyran-4-one group, a pyridine group, a pyrimidine group, a pyrazine group, a pyridazine group, a triazine group, a carbazole group, a dibenzofuran group, or a dibenzothiophene group.

19. The composition of claim 12,
wherein an amount of the etching controller is about 0.01 wt % to about 5 wt % based on 100 wt % of the composition.

20. The composition of claim 12,
wherein the composition has a pH of about −3.0 to about 1.0.
